(19) United States
(12) Patent Application Publication
(10) Pub. No.: US 2025/0234763 A1
(43) Pub. Date: Jul. 17, 2025

(54) DISPLAY DEVICE AND METHOD OF FABRICATING THE SAME

(71) Applicant: Samsung Display Co., LTD., Yongin-si (KR)

(72) Inventors: Seung Hyun PARK, Yongin-si (KR); Da Hye KIM, Yongin-si (KR); Nam Wook LEE, Yongin-si (KR)

(73) Assignee: Samsung Display Co., LTD., Yongin-si (KR)

(21) Appl. No.: 18/824,250

(22) Filed: Sep. 4, 2024

(30) Foreign Application Priority Data
Jan. 16, 2024 (KR) 10-2024-0006542

(51) Int. Cl. H10K 59/80; H10K 59/12; H10K 59/122

(52) U.S. Cl. CPC H10K 59/8792; H10K 59/1201; H10K 59/122

(57) ABSTRACT

A display device includes: a substrate; a first electrode on the substrate; a pixel defining layer on the first electrode; a dummy layer on the pixel defining layer; a light emitting layer on the first electrode and the dummy layer; and a second electrode on the light emitting layer, wherein at least one side surface of the dummy layer has a round cross section.

### CROSS REFERENCE TO RELATED APPLICATION(S)

This application claims priority from to and benefits of Korean Patent Application No. 10-2024-0006542, under 35 U.S.C. § 119, filed on Jan. 16, 2024, in the Korean Intellectual Property Office, the entire contents of which are incorporated herein by reference.

### BACKGROUND

### 1. Technical Field

Embodiments relate to a display device, and more particularly, to a display device capable of improving image quality and a method of fabricating the display device.

### 2. Description of the Related Art

Display devices are becoming increasingly important with the development of multimedia. Accordingly, various display devices such as liquid crystal display devices (LCDs) and organic light emitting diode display devices (OLEDs) are being developed.

Of the display devices, a self-light emitting display device includes a self-light emitting element such as an organic light emitting diode. The self-light emitting element may include two electrodes facing each other and a light emitting layer interposed between the two electrodes. In case that the self-light emitting element is an organic light emitting diode, electrons and holes provided from the two electrodes may be recombined in the light emitting layer to generate excitons. As the generated excitons change from an excited state to a ground state, light may be emitted.

A display device may include a color conversion element for realizing color by receiving light from an organic light emitting diode. For example, the color conversion element may receive blue light from the organic light emitting diode and emit blue, green and red light, so that an image having various colors may be viewed. The color conversion element may be disposed in the form of a separate substrate in the display device or may be directly integrated with elements in the display device.

### SUMMARY

Aspects of the disclosure provide a display device capable of improving image quality and a method of fabricating the display device.

However, embodiments are not limited to those set forth herein. The above and other embodiments will become more apparent to one of ordinary skill in the art to which the disclosure pertains by referencing the detailed description of the disclosure given below.

According to an embodiment, a display device may include: a substrate; a first electrode on the substrate; a pixel defining layer on the first electrode; a dummy layer on the pixel defining layer; a light emitting layer on the first electrode and the dummy layer; and a second electrode on the light emitting layer, wherein at least one side surface of the dummy layer may have a round cross section.

In an embodiment, the dummy layer may have an oval cross section.

In an embodiment, the dummy layer may comprise: a lower dummy layer including reverse-tapered side surfaces; and an upper dummy layer including forward-tapered side surfaces.

In an embodiment, the lower dummy layer may have a width that gradually increases as being farther from a lower surface of a lower dummy layer along a first direction from the dummy layer toward the first electrode on the dummy layer, and the upper dummy layer may have a width that gradually decreases as being closer to an upper surface of the dummy layer of the upper dummy layer along the first direction.

In an embodiment, the dummy layer may have at least one of green, red, blue, and black colors.

In an embodiment, the display device may further include a color filter and a light blocking pattern portion disposed on the light emitting layer on the first electrode, wherein the dummy layer and at least one of the color filter and the light blocking pattern portion may have the same color.

In an embodiment, the pixel defining layer may define a light emitting area corresponding to the light emitting layer on the first electrode, and the dummy layer may be disposed around the light emitting area in plan view.

In an embodiment, the pixel defining layer may define a plurality of light emitting areas, and at least a portion of the dummy layer may be disposed between adjacent light emitting areas in plan view.

In an embodiment, the dummy layer may have a line shape in plan view.

In an embodiment, the dummy layer may have a dotted shape in plan view.

In an embodiment, the dummy layer may include an organic material.

In an embodiment, the dummy layer may include a negative type organic material.

In an embodiment, the dummy layer may have a thickness of about 1 μm to about 6 μm.

In an embodiment, the light emitting layer on the first electrode and the light emitting layer on the dummy layer may be disconnected from each other.

In an embodiment, the light emitting layer may include: a main light emitting layer on the first electrode; and a dummy light emitting layer disposed on the dummy layer and separated from the main light emitting layer.

In an embodiment, the second electrode disposed on the light emitting layer to overlap the first electrode and the second electrode disposed on the light emitting layer to overlap the dummy layer may be disconnected from each other.

In an embodiment, the second electrode may include: a main second electrode disposed on the light emitting layer to overlap the first electrode; and a dummy second electrode disposed on the light emitting layer to overlap the dummy layer and separated from the main second electrode.

In an embodiment, the display device may further include a thin-film encapsulation layer on the second electrode, wherein the thin-film encapsulation layer may cover a broken portion of the light emitting layer.

In an embodiment, the display device may further include a capping layer between the second electrode and the thin-film encapsulation layer, wherein the capping layer may cover the broken portion of the light emitting layer.

In an embodiment, the display device may further include a wavelength conversion member on the thin-film encapsulation layer.

According to an embodiment, a method of fabricating a display device may include: forming a first electrode on a substrate; forming a pixel defining layer on the first electrode; forming a dummy layer on the pixel defining layer; forming a light emitting layer on the first electrode and the dummy layer; and forming a second electrode on the light emitting layer, wherein at least one side surface of the dummy layer may have a round cross section.

In an embodiment, the forming of the dummy layer may include: forming an organic material layer by applying a negative type organic material to an entire surface of the substrate including the first electrode and the pixel defining layer; placing a mask, which comprises an opening, above the organic material layer; exposing the organic material layer through the mask such that the organic material layer includes an exposed portion and an unexposed portion; and forming the dummy layer on the pixel defining layer by developing the exposed organic material layer to selectively leave the exposed portion among the exposed portion and the unexposed portion of the organic material layer.

In an embodiment, the dummy layer may have an oval cross section.

In an embodiment, the dummy layer may include: a lower dummy layer including reverse-tapered side surfaces; and an upper dummy layer comprising forward-tapered side surfaces.

In an embodiment, the lower dummy layer may have a width that gradually increases as being farther from the lower surface of the lower dummy layer along a first direction from the dummy layer toward the first electrode on the dummy layer, and the upper dummy layer may have a width that gradually decreases as being closer to the upper surface of the upper dummy layer along the first direction.

In an embodiment, the dummy layer may have at least one of green, red, blue, and black colors.

In an embodiment, the method may further include forming a color filter and a light blocking pattern portion on the light emitting layer on the first electrode, wherein the dummy layer and at least one of the color filter and the light blocking pattern portion may have the same color.

In an embodiment, the pixel defining layer may define a light emitting area corresponding to the light emitting layer on the first electrode, and the dummy layer is disposed around the light emitting area in plan view.

In the display device according to the disclosure, it provides a display device capable of improving image quality.

The effects according to an embodiments are not limited to those mentioned above and more various effects are included in the following description of the disclosure.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a display device according to an embodiment;

FIG. 2 is a schematic cross-sectional view taken along line X1-X1′ of FIG. 1;

FIG. 3 is a schematic plan view of the display device according to an embodiment;

FIG. 4 is an enlarged schematic plan view of area A1 of FIG. 3;

FIG. 5 is an enlarged schematic plan view of area A1 of FIG. 3;

FIG. 6 is a schematic cross-sectional view taken along line X2-X2′ of FIGS. 4 and 5;

FIG. 7 is an enlarged schematic cross-sectional view of area A2 of FIG. 6;

FIG. 8 is an enlarged schematic cross-sectional view of area A3 of FIG. 6;

FIG. 9 is a schematic plan view illustrating the schematic arrangement of a first color filter of a color filter member included in a light transmitting unit of the display device according to an embodiment and a dummy layer;

FIG. 10 is a schematic plan view illustrating the schematic arrangement of a second color filter of the color filter member included in the light transmitting unit of the display device according to an embodiment and the dummy layer;

FIG. 11 is a schematic plan view illustrating the schematic arrangement of a third color filter of the color filter member included in the light transmitting unit of the display device according to an embodiment and the dummy layer;

FIG. 12 is a schematic diagram of an equivalent circuit of a pixel circuit of the display device according to an embodiment;

FIG. 13 is another schematic plan view of area A1 of FIG. 3, and a schematic plan view of a light emitting unit and a dummy layer included in the display device of FIG. 3;

FIG. 14 is another schematic plan view of area A1 of FIG. 3, and a schematic plan view of a light emitting unit and a dummy layer included in the display device of FIG. 3;

FIG. 15 is another schematic plan view of area A1 of FIG. 3, and a schematic plan view of a light emitting unit and a dummy layer included in the display device of FIG. 3;

FIGS. 16 through 22 are cross-sectional views for explaining a method of fabricating a display device according to an embodiment;

FIG. 23 is a schematic diagram for explaining the effect of preventing lateral leakage current between adjacent pixels by a dummy layer in a display device according to an embodiment;

FIG. 24 is a chromaticity distribution diagram;

FIG. 25 illustrates a peak value for each wavelength of a display device according to an embodiment; and

FIG. 26 is a focused ion beam (FIB) image of a dummy layer of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments will be described with reference to the accompanying drawings.

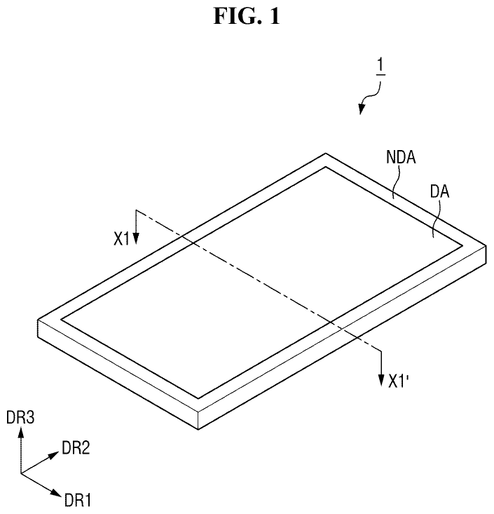

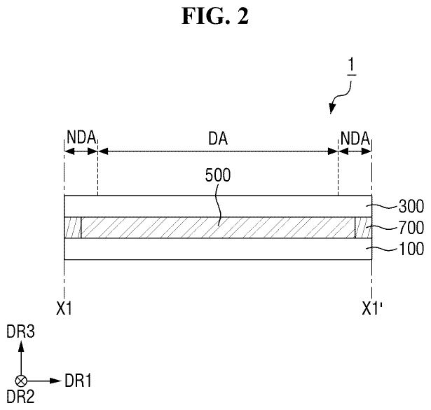

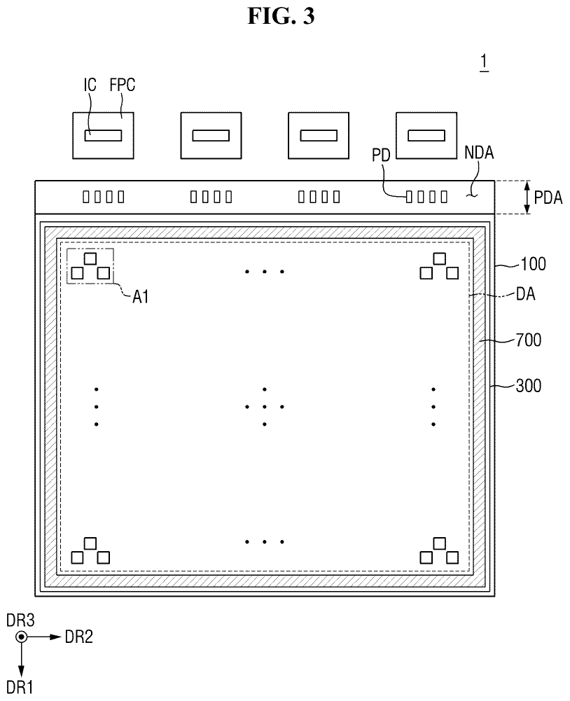

FIG. 1 is a schematic perspective view of a display device 1 according to an embodiment. FIG. 2 is a schematic cross-sectional view taken along line X1-X1′ of FIG. 1. FIG. 3 is a schematic plan view of the display device 1 according to the embodiment.

Referring to FIGS. 1 and 2, the display device 1 according to the embodiment may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). In another example, the display device 1 according to an embodiment may be applied as a display unit of a television, a laptop computer, a monitor, a billboard, or an Internet of things (IoT) device. However, these are presented only as examples, and the display device 1 according to an embodiment may also be implemented in other electronic devices.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a vertical direction in the drawing, the second direction DR2 refers to a horizontal direction in the drawing, and the third direction DR3 refers to an up-down direction in the drawing, e.g., a thickness direction. In the following description, unless otherwise specified, a “direction” may refer to directions (e.g., opposite directions) extending to sides (e.g., opposite sides) along the direction. For example, in case that it is necessary to distinguish “directions” extending to sides (e.g., opposite sides), a side will be referred to as a “first side in the direction,” and another side will be referred to as a “second side in the direction.” Based on FIG. 1, a direction in which an arrow is directed will be referred to as the first side, and a direction opposite to the direction will be referred to as the second side.

For descriptive convenience, in referring to surfaces of the display device 1 or each member constituting the display device 1, a surface facing the first side in a direction in which an image is displayed, e.g., in the third direction DR3 will be referred to as an upper surface, and another surface opposite to the surface will be referred to as a lower surface. However, embodiments are not limited thereto, and the surface and another surface of each member may also be referred to as a front surface and a rear surface or as a first surface and a second surface, respectively. For example, in describing relative positions of the members of the display device 1, the first side in the third direction DR3 may be referred to as an upper side, and the second side in the third direction DR3 may be referred to as a lower side.

The display device 1 may have a three-dimensional (3D) shape. For example, the display device 1 may have a rectangular parallelepiped shape or a 3D shape similar to the rectangular parallelepiped shape. In some embodiments, the display device 1 may have a planar shape similar to a quadrilateral. For example, the display device 1 according to the embodiment may have a planar shape similar to a quadrilateral having short sides in the first direction DR1 and long sides in the second direction DR2 as illustrated in FIG. 1. However, embodiments are not limited thereto. For example, in the planar shape of the display device 1 according to the embodiment, each corner where a short side extending in the first direction DR1 meets a long side extending in the second direction DR2 may be rounded with a predetermined curvature or may be right-angled. The planar shape of the display device 1 is not limited to a quadrilateral shape but may also be similar to other polygonal shapes, a circular shape, or an oval shape.

The display device 1 may include a display area DA in which a screen is displayed and a non-display area NDA in which a screen is not displayed. In some embodiments, the non-display area NDA may surround edge portions of the display area DA, but embodiments are not limited thereto. An image displayed in the display area DA may be viewed by a user from the first side in the third direction DR3 based on FIG. 1.

As illustrated in FIG. 2, the display device 1 may include a light emitting unit 100 and a color filter unit 300 facing the light emitting unit 100 and may further include a sealing member 700 bonding the light emitting unit 100 and the color filter unit 300 together and a filler 500 filling a space between the light emitting unit 100 and the color filter unit 300.

The light emitting unit 100 may include elements and circuits for displaying an image, for example, a pixel circuit such as a switching element, a pixel defining layer 170 defining a light emitting area and a non-light emitting area, which will be described later, in the display area DA, and a self-light emitting element. In an embodiment, the self-light emitting element may include at least one of an organic light emitting diode, a quantum dot light emitting diode, an inorganic material-based micro light emitting diode (e.g., micro LED), and an inorganic material-based nano light emitting diode (e.g., nano LED). For descriptive convenience, a case where the self-light emitting element is an organic light emitting diode will be described below as an example. For example, the light emitting unit 100 may include a light transmitting member (e.g., a first light transmitting member TPL, a second light transmitting member WCL1, and a third light transmitting member WCL2) for converting the color of incident light emitted from the above self-light emitting element and irradiated to the color filter unit 300. In some embodiments, the light transmitting member may include at least any one of wavelength conversion shifters and light scatterers as will be described later.

The color filter unit 300 may be positioned on the light emitting unit 100 and may face the light emitting unit 100. In some embodiments, the color filter unit 300 may include a color conversion pattern for converting the color of incident light provided from the light emitting unit 100. In some embodiments, the color filter unit 300 may include a color filter member 320, which will be described later, as the color conversion pattern.

The sealing member 700 may be positioned between the light emitting unit 100 and the color filter unit 300 in the non-display area NDA. The sealing member 700 may be disposed along edge portions of the light emitting unit 100 and the color filter unit 300 in the non-display area NDA to surround the display area DA in plan view. The light emitting unit 100 and the color filter unit 300 may be bonded to each other by the sealing member 700.

In some embodiments, the sealing member 700 may be made of an organic material. For example, the sealing member 700 may be made of epoxy resin, but embodiments are not limited thereto. In some embodiments, the sealing member 700 may be applied in the form of a frit including glass or the like.

The filler 500 may be positioned in the space disposed between the light emitting unit 100 and the color filter unit 300 and surrounded by the sealing member 700. The filler 500 may fill the space between the light emitting unit 100 and the color filter unit 300.

In some embodiments, the filler 500 may be made of a material that may transmit light. In some embodiments, the filler 500 may be made of an organic material. For example, the filler 500 may be made of a silicon-based organic material, an epoxy-based organic material, or a mixture of a silicon-based organic material and an epoxy-based organic material.

FIG. 3 is a schematic plan view of the display device 1 according to an embodiment.

Referring to FIG. 3, the display device 1 may further include flexible circuit boards FPC and driving chips IC.

The non-display area NDA of the display device 1 may include a pad area PDA, and connection pads PD may be positioned in the pad area PDA. The pad area PDA may be defined on the light emitting unit 100. Accordingly, the connection pads PD may be disposed on the light emitting unit 100.

The flexible circuit boards FPC may be connected to the connection pads PD. The flexible circuit boards FPC may electrically connect the light emitting unit 100 to a circuit board that provides signals and power for driving the display device 1.

The driving chips IC may be electrically connected to the circuit board to receive data and signals. In some embodiments, the driving chips IC may be data driving chips IC and may receive a data control signal and image data from the circuit board and generate and output data voltages corresponding to the image data.

In some embodiments, the driving chips IC may be mounted on the flexible circuit boards FPC. For example, the driving chips IC may be mounted on the flexible circuit boards FPC in the form of chips on films (COF).

The data voltages provided from the driving chips IC, the power provided from the circuit board, etc. may be transmitted to pixel circuits of the light emitting unit 100 via the flexible circuit boards FPC and the connection pads PD as will be described later.

Light emitting areas defined in the light emitting unit 100 of the display device 1 and light transmitting areas defined in the color filter unit 300 will now be described in more detail.

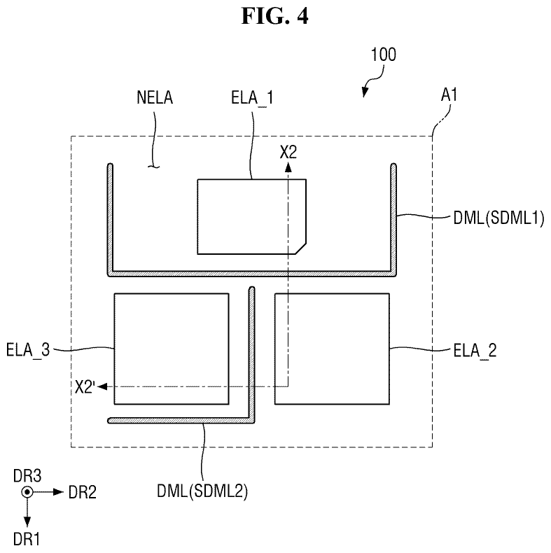

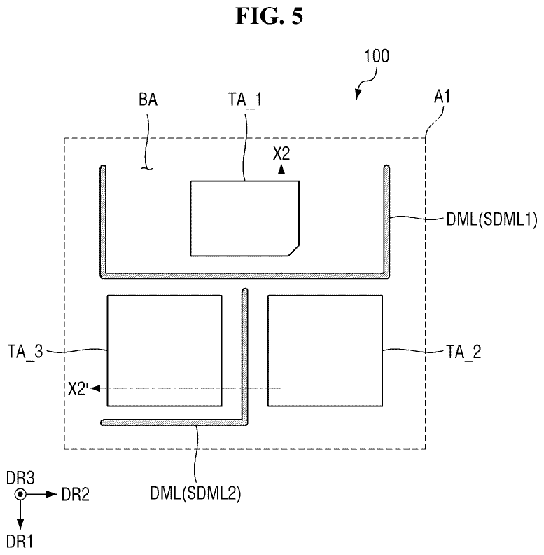

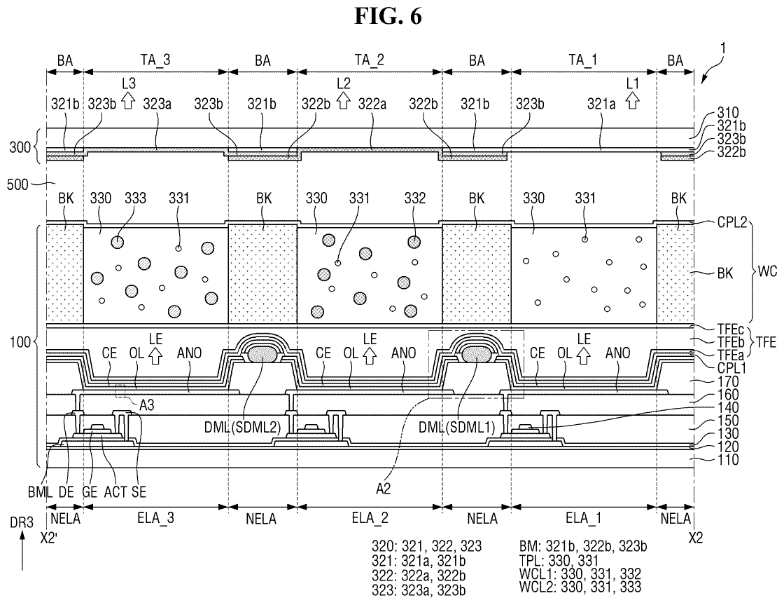

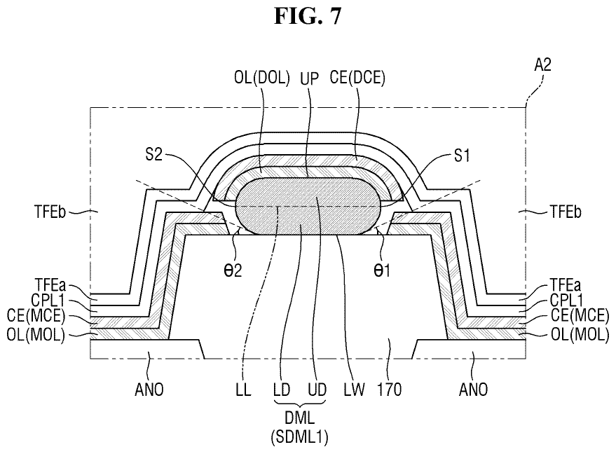

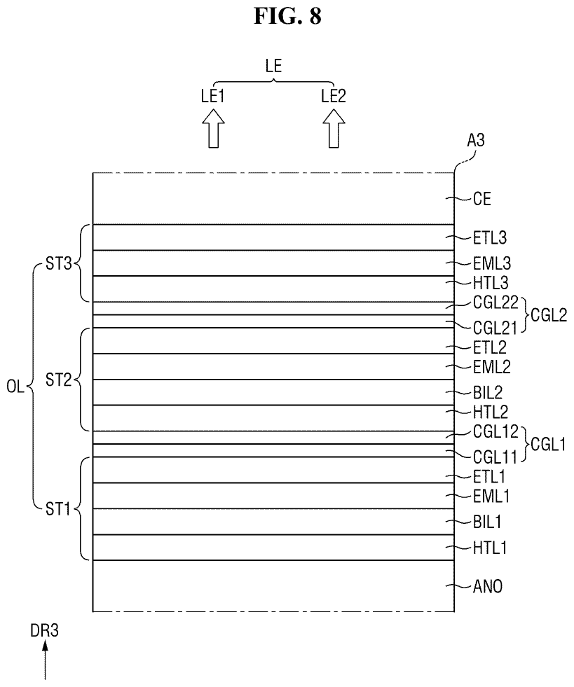

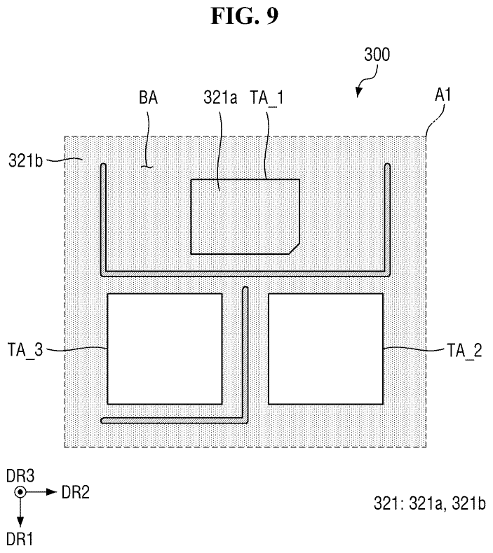

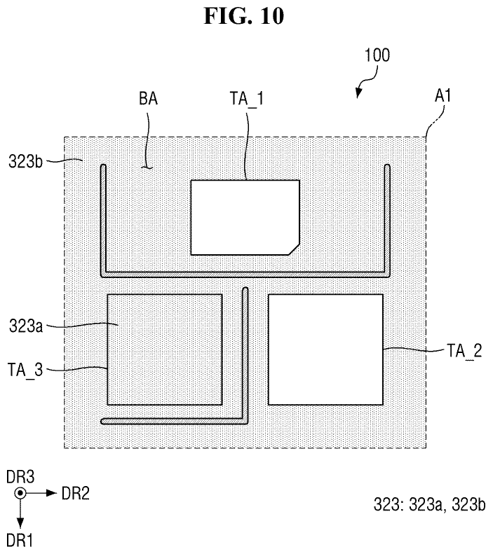

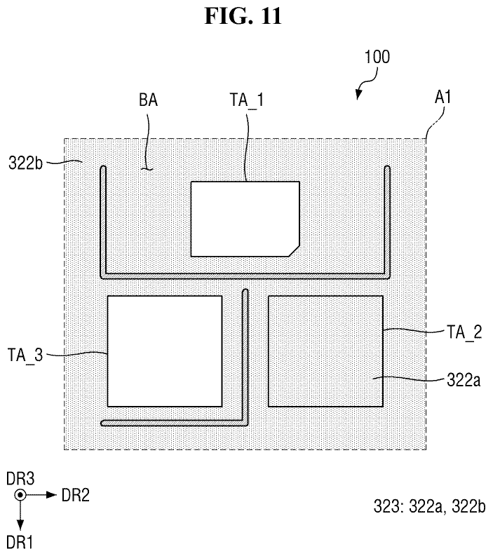

FIG. 4 is an enlarged schematic plan view of area A1 of FIG. 3, and is a schematic plan view of the light emitting unit 100 and a dummy layer DML included in the display device 1 of FIG. 3. FIG. 5 is an enlarged schematic plan view of area A1 of FIG. 3, and a schematic plan view of a light transmitting unit and the dummy layer DML included in the display device 1 of FIG. 3. FIG. 6 is a schematic cross-sectional view taken along line X2-X2′ of FIGS. 4 and 5. FIG. 7 is an enlarged schematic cross-sectional view of area A2 of FIG. 6. FIG. 8 is an enlarged cross-sectional view of area A3 of FIG. 6. FIG. 9 is a schematic plan view illustrating the schematic arrangement of a first color filter 321 of the color filter member 320 included in the light transmitting unit of the display device 1 according to an embodiment and the dummy layer DML. FIG. 10 is a schematic plan view illustrating the schematic arrangement of a second color filter 322 of the color filter member 320 included in the light transmitting unit of the display device 1 according to an embodiment and the dummy layer DML. FIG. 11 is a schematic plan view illustrating the schematic arrangement of a third color filter 323 of the color filter member 320 included in the light transmitting unit of the display device 1 according to an embodiment and the dummy layer DML.

Referring to FIGS. 4 through 6 in addition to FIG. 3, light emitting areas may be defined in the light emitting unit 100 of the display device 1 according to an embodiment, and light transmitting areas may be defined in the color filter unit 300.

The display area DA and the non-display area NDA defined in the display device 1 may be applied to the light emitting unit 100 and the color filter unit 300.

A first light emitting area ELA_1, a second light emitting area ELA_2, and a third light emitting area ELA_3 may be defined in the display area DA of the light emitting unit 100 as illustrated in FIG. 4. The first light emitting area ELA_1, the second light emitting area ELA_2, and the third light emitting area ELA_3 may be areas where light generated by light emitting elements of the light emitting unit 100 is emitted to the outside of the light emitting unit 100. A non-light emitting area NELA may be an area where light is not emitted to the outside of the light emitting unit 100. In some embodiments, the non-light emitting area NELA may surround the first light emitting area ELA_1, the second light emitting area ELA_2, and the third light emitting area ELA_3 in the display area DA, but embodiments are limited thereto.

In some embodiments, light emitted from the first light emitting area ELA_1, the second light emitting area ELA_2 and the third light emitting area ELA_3 to the outside may be light of a first color. In some embodiments, the light of the first color may be blue light and may have a peak wavelength in the range of about 440 nm to about 480 nm. For example, the peak wavelength refers to a wavelength at which the intensity of light is maximum.

In some embodiments, as illustrated in FIG. 4, the third light emitting area ELA_3 and the second light emitting area ELA_2 may be sequentially positioned along the second direction DR2. The first light emitting area ELA_1 may be positioned on a side of a space between the third light emitting area ELA_3 and the second light emitting area ELA_2. The first light emitting area ELA_1, the second light emitting area ELA_2, and the third light emitting area ELA_3 may form one group.

As illustrated in FIG. 3, one group formed by the first light emitting area ELA_1, the second light emitting area ELA_2, and the third light emitting area ELA_3 may be repeatedly disposed along the first direction DR1 and the second direction DR2 in the display area DA. However, embodiments are not limited thereto. For example, the arrangement of the first light emitting area ELA_1, the second light emitting area ELA_2, and the third light emitting area ELA_3 may be changed variously. Therefore, the first light emitting area ELA_1, the second light emitting area ELA_2, and the third light emitting area ELA_3 may also be sequentially positioned along the second direction DR2. For descriptive convenience, a case where the first light emitting area ELA_1, the second light emitting area ELA_2, and the third light emitting area ELA_3 are arranged as illustrated in FIG. 4 will be described below as an example.

In some embodiments, the area (or size) of the first light emitting area ELA_1, the area (or size) of the second light emitting area ELA_2, and the area (or size) of the third light emitting area ELA_3 may be substantially the same. However, embodiments are not limited thereto. For example, the area (or size) of the first light emitting area ELA_1, the area (or size) of the second light emitting area ELA_2, and the area (or size) of the third light emitting area ELA_3 may also be different from each other. In some embodiments, the first light emitting area ELA_1, the second light emitting area ELA_2, and the third light emitting area ELA_3 may have a polygonal planar shape, but embodiments are not limited thereto. For descriptive convenience, an example in which the second light emitting area ELA_2 and the third light emitting area ELA_3 have a quadrilateral planar shape and have substantially the same area, and the first light emitting area ELA_1 has a pentagonal planar shape and has a smaller area than the second light emitting area ELA_2 (or the third light emitting area ELA_3) will be described below.

A first light transmitting area TA_1, a second light transmitting area TA_2, and a third light transmitting area TA_3 may be defined in the display area DA of the color filter unit 300. The first light emitting area TA_1, the second light transmitting area TA_2, and the third light emitting area TA_3 may be areas through which light generated from the first light emitting area ELA_1, the second light emitting area ELA_2, and the third light emitting area ELA_3 of the light emitting unit 100 is transmitted. A light blocking area BA may be positioned around the first light transmitting area TA_1, the second light transmitting area TA_2, and the third light transmitting area TA_3 in the display area DA of the color filter unit 300. In some embodiments, the light blocking area BA may surround the first light transmitting area TA_1, the second light transmitting area TA_2, and the third light transmitting area TA_3. However, embodiments are not limited thereto. For example, the light blocking area BA may be positioned in the non-display area NDA as well as in the display area DA of the color filter unit 300.

The first light transmitting area TA_1 may correspond to (or overlap) the first light emitting area ELA_1, the second light transmitting area TA_2 may correspond to (or overlap) the second light emitting area ELA_2, and the third light transmitting area TA_3 may correspond to (or overlap) the third light emitting area ELA_3. In some embodiments, the first light transmitting area TA_1 may have substantially the same area as the first light emitting area ELA_1 and overlap (e.g., completely overlap) the first light emitting area ELA_1, the second light transmitting area TA_2 may have substantially the same area as the second light emitting area ELA_2 and overlap (e.g., completely overlap) the second light emitting area ELA_2, and the third light transmitting area TA_3 may have substantially the same area as the third light emitting area ELA_3 and overlap (e.g., completely overlap) the third light emitting area ELA_3. However, embodiments are not limited thereto. For example, the first light emitting area TA_1 may also have a different area from the first light emitting area ELA_1, the second light transmitting area TA_2 may also have a different area from the second light emitting area ELA_2, and the third light transmitting area TA_3 may also have a different area from the third light emitting area ELA_3. For descriptive convenience, a case where the first light transmitting area TA_1 has substantially the same area as the first light emitting area ELA_1 and overlaps (e.g., completely overlaps) the first light emitting area ELA_1, the second light transmitting area TA_2 has substantially the same area as the second light emitting area ELA_2 and overlaps (e.g., completely overlaps) the second light emitting area ELA_2, and the third light transmitting area TA_3 has substantially the same area as the third light emitting area ELA_3 and overlap (e.g., completely overlaps) the third light emitting area ELA_3 will be described below.

Accordingly, the third light transmitting area TA_3 and the second light transmitting area TA_2 may be sequentially positioned along the second direction DR2. The first light transmitting area TA_1 may be positioned on a side of a space between the third light transmitting area TA_3 and the second light transmitting area TA_2. The first light transmitting area TA_1, the second light transmitting area TA_2, and the third light transmitting area TA_3 may form one group. As illustrated in FIG. 3, one group formed by the first light transmitting area TA_1, the second light transmitting area TA_2, and the third light transmitting area TA_3 may be repeatedly disposed along the first direction DR1 and the second direction DR2 in the display area DA.

As described above, light of the first color emitted from the light emitting unit 100 may be provided to the outside of the display device 1 through the first light transmitting area TA_1, the second light transmitting area TA_2, and the third light transmitting area TA_3. Light output from the first light transmitting area TA_1 to the outside of the display device 1 may be referred to as first output light, light output from the second light transmitting area TA_2 to the outside of the display device 1 may be referred to as second output light, and light output from the third light transmitting area TA_3 to the outside of the display device 1 may be referred to as third output light. For example, the first output light may be light of the first color, the second output light may be light of a second color, and the third output light may be light of a third color.

In some embodiments, the light of the first color may be blue light having a peak wavelength in the range of about 440 nm to about 480 nm as described above, and the light of the second color may be green light having a peak wavelength in the range of about 510 to about 550 nm. For example, the light of the third color may be red light having a peak wavelength in the range of about 610 nm to about 650 nm.

As illustrated in FIG. 4, the dummy layer DML may be disposed in the non-light emitting area NELA in plan view. In some embodiments, the dummy layer DML may be disposed in a boundary portion between the first through third light emitting areas ELA_1 through ELA_3 that form one group. For example, the dummy layer DML may include a first sub-dummy layer SDML1 and a second sub-dummy layer SDML2. The first sub-dummy layer SDML1 may be disposed between the first light emitting area ELA_1 and the second light emitting area ELA_2 and between the first light emitting area ELA_1 and the third light emitting area ELA_3. For example, the second sub-dummy layer SDML2 may be disposed between the second light emitting area ELA_2 and the third light emitting area ELA_3. According to an embodiment, the dummy layer DML may have a line shape in plan view.

According to some embodiments, the first sub-dummy layer SDML1 may have a U shape surrounding all surfaces (or at least one surface) of the first light emitting area ELA_1, and the second sub-dummy layer SDML2 may have an L shape (e.g., an L shape inverted by about 180 degrees with respect to the first direction DR1) facing two adjacent surfaces of the third light emitting area ELA_3. For example, at least a portion of the U-shaped first sub-dummy layer SDML1 may be disposed between the first light emitting area ELA_1 and the second light emitting area ELA_2 and between the first light emitting area ELA_1 and the third light emitting area ELA_3 as described above. For example, at least a portion of the inverted L-shaped second sub-dummy layer SDML2 may be disposed between the second light emitting area ELA_2 and the third light emitting area ELA_3 as described above.

As illustrated in FIG. 5, the above-described dummy layer DML may be disposed in the light blocking area BA in plan view. In some embodiments, the dummy layer DML may be disposed in a boundary portion between the first through third light transmitting areas TA_1 through TA_3 that form one group. For example, as described above, the dummy layer DML may include the first sub-dummy layer SDML1 and the second sub-dummy layer SDML2. The first sub-dummy layer SDML1 may be disposed between the first light transmitting area TA_1 and the second light transmitting area TA_2 and between the first light transmitting area TA_1 and the third light transmitting area TA_3. For example, the second sub-dummy layer SDML2 may be disposed between the second light transmitting area TA_2 and the third light transmitting area TA_3.

According to some embodiments, the first sub-dummy layer SDML1 may have a U-shape surrounding all surfaces (or at least one surface) of the first light transmitting area TA_1, and the second sub-dummy layer SDML2 may have an L shape (e.g., an L shape inverted by about 180 degrees with respect to the first direction DR1) facing two adjacent surfaces of the third light transmitting area TA_3. For example, at least a portion of the U-shaped first sub-dummy layer SDML1 may be disposed between the first light transmitting area TA_1 and the second light transmitting area TA_2 and between the first light transmitting area TA_1 and the third light transmitting area TA_3 as described above. For example, at least a portion of the inverted L-shaped second sub-dummy layer SDML2 may be disposed between the second light transmitting area TA_2 and the third light transmitting area TA_3 as described above. The structure of the display device 1 will now be described in detail.

Referring to FIG. 6, as described above, the display device 1 may include the light emitting unit 100, the color filter unit 300 disposed on the light emitting unit 100 to face the light emitting unit 100, and the filler 500 interposed between the light emitting unit 100 and the color filter unit 300. For descriptive convenience, the light emitting unit 100, the color filter unit 300, and the filler 500 will be described below in this order.

The light emitting unit 100 may have a structure in which a first substrate 110, a buffer layer 120, bottom metal layers BML, a first insulating layer 130, semiconductor layers ACT, gate electrodes GE, gate insulating layers 140, a second insulating layer 150, source/drain electrodes, a third insulating layer 160, light emitting elements, a pixel defining layer 170, the dummy layer DML, a first capping layer CPL1, a thin-film encapsulation layer TFE, and a wavelength conversion member WC are sequentially stacked to the first side in the third direction DR3.

The first substrate 110 of the light emitting unit 100 may function as a base of the light emitting unit 100. The first substrate 110 may be made of a light transmitting material. The first substrate 110 may be a glass substrate or a plastic substrate. In case that the first substrate 110 is a plastic substrate, it may have flexibility. In some embodiments, in case that the first substrate 110 is a plastic substrate, it may include polyimide. However, embodiments are not limited thereto.

The buffer layer 120 of the light emitting unit 100 may be disposed on the first substrate 110. The buffer layer 120 may block foreign substances or moisture introduced through the first substrate 110 from entering elements disposed on the buffer layer 120.

In some embodiments, the buffer layer 120 may include an inorganic material such as SiO₂, SiNₓ or SiON and may be formed as a single layer or a multilayer, but embodiments are not limited thereto.

The bottom metal layers BML of the light emitting unit 100 may be disposed on the buffer layer 120. The bottom metal layers BML may block external light or light emitted from the light emitting elements to be described later from entering the semiconductor layers ACT. Accordingly, it is possible to prevent leakage current from being generated by light in thin-film transistors which will be described later or may reduce the generation of the leakage current.

The bottom metal layers BML may be made of a material that blocks light and has conductivity. In some embodiments, the bottom metal layers BML may include a single material selected from metals such as silver (Ag), nickel (Ni), gold (Au), platinum (Pt), aluminum (Al), copper (Cu), molybdenum (Mo), titanium (Ti) and neodymium (Nd) or may include an alloy of the metals. In some embodiments, the bottom metal layers BML may have a single-layer structure or a multilayer structure. For example, in case that the bottom metal layers BML have a multilayer structure, each of the bottom metal layers BML may be a stacked structure of titanium (Ti)/copper (Cu)/indium tin oxide (ITO) or a stacked structure of titanium (Ti)/copper (Cu)/aluminum oxide (Al₂O₃). However, embodiments are not limited thereto.

In some embodiments, the bottom metal layers BML may correspond to (or overlap) the semiconductor layers ACT and overlap the semiconductor layers ACT, respectively. In some embodiments, the bottom metal layers BML may be wider than the semiconductor layers ACT.

In some embodiments, the bottom metal layers BML may be part of data lines, power supply lines, and lines that electrically connect thin-film transistors not illustrated in the drawing to the thin-film transistors (GE, ACT, DE and SE in FIG. 6) illustrated in the drawing. In some embodiments, the bottom metal layers BML may be made of a material having a smaller resistance than source electrodes SE and drain electrodes DE.

The first insulating layer 130 of the light emitting unit 100 may be disposed on the bottom metal layers BML. The first insulating layer 130 may electrically insulate the bottom metal layers BML from the semiconductor layers ACT. The first insulating layer 130 may cover the bottom metal layers BML.

In some embodiments, the first insulating layer 130 may include an inorganic material such as SiO₂, SiNₓ, SiON, Al₂O₃, TiO₂, Ta₂O, HfO₂, or ZrO₂. However, embodiments are not limited thereto.

The semiconductor layers ACT of the light emitting unit 100 may be disposed on the first insulating layer 130. The semiconductor layers ACT may respectively correspond to (or overlap) the first light emitting area ELA_1, the second light emitting area ELA_2, and the third light emitting area ELA_3 in the display area DA of the light emitting unit 100. For example, the semiconductor layers ACT may overlap the bottom metal layers BML, respectively. Accordingly, generation of photocurrent in the semiconductor layers ACT may be suppressed.

The semiconductor layers ACT may include an oxide semiconductor. In some embodiments, each of the semiconductor layers ACT may be made of a Zn oxide-based material such as Zn oxide, In—Zn oxide or Ga—In—Zn oxide or maybe an In—Ga—Zn—O (IGZO) semiconductor containing metals such as indium (In) and gallium (Ga) in ZnO. However, embodiments are not limited thereto. For example, the semiconductor layers ACT may also include amorphous silicon or polysilicon.

The gate electrodes GE of the light emitting unit 100 may be disposed on the semiconductor layers ACT. The gate electrodes GE may overlap the semiconductor layers ACT in the display area DA. In some embodiments, the gate electrodes GE may be narrower than the semiconductor layers ACT, but embodiments are not limited thereto.

In some embodiments, in consideration of adhesion to an adjacent layer, surface flatness of a layer on which it is stacked, and workability, each of the gate electrodes GE may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and copper (Cu) and may be formed as a single layer or a multilayer, but embodiments are not limited thereto.

The gate insulating layers 140 of the light emitting unit 100 may be disposed between the semiconductor layers ACT and the gate electrodes GE. The gate insulating layers 140 may insulate the semiconductor layers ACT from the gate electrodes GE. In some embodiments, the gate insulating layers 140 may have a partially patterned shape instead of being formed as a single layer on a surface of the first substrate 110 on the first side in the third direction DR3. The gate insulating layers 140 may be narrower than the semiconductor layers ACT and may be wider than the gate electrodes GE, but embodiments are not limited thereto.

In some embodiments, the gate insulating layers 140 may include an inorganic material. For example, the gate insulating layers 140 may include one of the inorganic materials mentioned in the description of the first insulating layer 130.

The second insulating layer 150 of the light emitting unit 100 may be disposed on the gate insulating layers 140 to cover the semiconductor layers ACT and the gate electrodes GE. In some embodiments, the second insulating layer 150 may function as a planarization layer that provides a flat surface.

The second insulating layer 150 may include an organic material. In some embodiments, the second insulating layer 150 may include at least any one of photo acryl (PAC), polystyrene, polymethyl methacrylate (PMMA), polyacrylonitrile (PAN), polyamide, polyimide, polyarylether, heterocyclic polymer, parylene, fluorine-based polymer, epoxy resin, benzocyclobutene series resin, siloxane series resin, and silane resin. However, embodiments are not limited thereto.

The source electrodes SE and the drain electrodes DE of the light emitting unit 100 may be spaced apart from each other on the second insulating layer 150. The source electrodes SE and the drain electrodes DE may be connected to the semiconductor layers ACT respectively through contact holes penetrating the second insulating layer 150. In some embodiments, the source electrodes SE may penetrate the first insulating layer 130 as well as the second insulating layer 150 and thus may be connected to the bottom metal layers BML. In case that the bottom metal layers BML are part of lines that transmit signals or voltages, the source electrodes SE may be connected and electrically coupled to the bottom metal layers BML to receive voltages provided to the lines. In another example, in case that the bottom metal layers BML are floating patterns rather than lines, voltages provided to the source electrodes SE may be transmitted to the bottom metal layers BML.

Each of the source electrodes SE and the drain electrodes DE may include aluminum (Al), copper (Cu), titanium (Ti), or the like and may be formed as a multilayer or a single layer. In some embodiments, the source electrodes SE and the drain electrodes DE may have a multilayer structure of Ti/Al/Ti. However, embodiments are not limited thereto.

The semiconductor layers ACT, the gate electrodes GE, the source electrodes SE, and the drain electrodes DE described above may form thin-film transistors which are switching elements. In some embodiments, the thin-film transistors may be positioned in the first light emitting area ELA_1, the second light emitting area ELA_2, and the third light emitting area ELA_3, respectively. In some embodiments, a portion of each of the thin-film transistors may be positioned in the non-light emitting area NELA.

The third insulating layer 160 of the light emitting unit 100 may be disposed on the second insulating layer 150 to cover the thin-film transistors. In some embodiments, the third insulating layer 160 may be a planarization layer.

The third insulating layer 160 may be made of an organic material. In some embodiments, the third insulating layer 160 may include acrylic resin, epoxy resin, imide resin or ester resin or may include a photosensitive organic material, but embodiments are not limited thereto.

Anodes ANO (or first electrodes) may be positioned on the third insulating layer 160 in the display area DA of the light emitting unit 100.

The anodes ANO may overlap the first light emitting area ELA_1, the second light emitting area ELA_2 and the third light emitting area ELA_3, respectively, and at least a portion of each of the anodes ANO may extend to the non-light emitting area NELA. The anodes ANO may be connected to the drain electrodes DE of the thin-film transistors.

In some embodiments, the anodes ANO may be reflective electrodes. For example, each of the anodes ANO may be a metal layer including a metal such as Ag, Mg, A1, Pt, Pd, Au, Ni, Nd, Ir or Cr. In an embodiment, each of the anodes ANO may further include a metal oxide layer stacked on the metal layer. In an embodiment, the anodes ANO may have a multilayer structure, for example, a two-layer structure of ITO/Ag, Ag/ITO, ITO/Mg or ITO/MgF or a three-layer structure of ITO/Ag/ITO.

The pixel defining layer 170 of the light emitting unit 100 may be disposed on the anodes ANO. The pixel defining layer 170 may define the first light emitting area ELA_1, the second light emitting area ELA_2, and the third light emitting area ELA_3 as openings that expose the anodes ANO. For example, the pixel defining layer 170 may include the openings that expose the anodes ANO and correspond to (or overlap) the first light emitting area ELA_1, the second light emitting area ELA_2, and the third light emitting area ELA_3.

The pixel defining layer 170 may overlap the light blocking area BA of the color filter member 320, which will be described later, in the third direction DR3. For example, the pixel defining layer 170 may overlap a bank member BK, which will be described later, in the third direction DR3.

In some embodiments, the pixel defining layer 170 may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB). However, embodiments are not limited thereto.

The dummy layer DML of the light emitting unit 100 may be disposed on the pixel defining layer 170 as illustrated in FIGS. 6 and 7. The dummy layer DML may overlap the pixel defining layer 170 and contact the pixel defining layer 170. At least one side surface of the dummy layer DML may have a round cross section. According to an embodiment, the dummy layer DML may have an oval cross section. The dummy layer DML may be made of a material including an organic material. For example, the dummy layer DML may include a negative type organic material cured by at least one of ultraviolet light and heat.

In some embodiments, the dummy layer DML may have a specific color. For example, the dummy layer DML may have a red color. In an embodiment for this purpose, the dummy layer DML may include a red colorant. As used herein, the term “colorant” is a concept encompassing both a dye and a pigment. In an embodiment, the dummy layer DML may be made of an organic material layer including a red colorant. However, embodiments are not limited thereto, and the dummy layer DML may also have a color other than red, for example, any one of green, blue, and black. In an embodiment, the dummy layer DML may be made of the same material as any one of the first color filter 321, the second color filter 322, the third color filter 323 and a light blocking pattern portion BM which will be described later.

As illustrated in FIG. 7, an upper surface UP and a lower surface LW of the dummy layer DML may face (or be opposite to) each other in the third direction DR3. A first side surface S1 of the dummy layer DML may be disposed between a side of the upper surface UP and a side of the lower surface LW, and a second side surface S2 of the dummy layer DML may be disposed between another side of the upper surface UP and another side of the lower surface LW. Each of the first side surface S1 and the second side surface S2 of the dummy layer DML may have a round shape. For example, the first side surface S1 and the second side surface S2 may be symmetrical by about 180 degrees with respect to the third direction DR3.

An imaginary horizontal line LL crossing a central portion of the dummy layer DML (e.g., a central portion of the first side surface S1 and a central portion of the second side surface S2) between the lower surface LW and the upper surface UP of the dummy layer DML and substantially parallel to the lower surface LW (or the upper surface UP) of the dummy layer DML may be set. For example, the dummy layer DML may be defined as an upper dummy layer UD disposed above the imaginary horizontal line LL and a lower dummy layer LD disposed below the imaginary horizontal line LL.

The upper dummy layer UD may have a width that gradually decreases as being closer to the upper surface UP of the upper dummy layer UD along the third direction DR3, and the lower dummy layer LD may have a width that gradually increases as being farther from the lower surface LW of the lower dummy layer LD along the third direction DR3. For example, the upper dummy layer UD may have a forward-tapered shape based on the third direction DR3, and the lower dummy layer LD may have a reverse-tapered shape based on the third direction DR3. For example, the width may mean the size of the dummy layer DML in the first direction DR1 (or the second direction DR2).

A first angle θ1 between the first side surface S1 of the lower dummy layer LD and an upper surface of the pixel defining layer 170 may be defined as a first reverse taper angle, and the first reverse taper angle may be greater than about 30 degrees and smaller than about 90 degrees. Likewise, a second angle θ2 between the second side surface S2 of the lower dummy layer LD and the upper surface of the pixel defining layer 170 may be defined as a second reverse taper angle, and the second reverse taper angle may be greater than about 30 degrees and smaller than about 90 degrees.

The light emitting layer OL of the light emitting unit 100 may be disposed on the anodes ANO. In some embodiments, the light emitting layer OL may be in the shape of a layer formed over the light emitting areas ELA_1 through ELA_3 and the non-light emitting area NELA. In some embodiments, the light emitting layer OL may be positioned only in the display area DA. However, embodiments are not limited thereto. For example, a portion of the light emitting layer OL may be further disposed in the non-display area NDA. For example, the light emitting layer OL may be further disposed on the pixel defining layer 170 and the dummy layer DML.

In some embodiments, the dummy layer DML may have a thickness of about 1 μm to about 6 μm. For example, the thickness of the dummy layer DML may mean the size (or thickness) of the dummy layer DML in the third direction DR3.

In some embodiments, a portion of the light emitting layer OL may be broken or disconnected. For example, at least a portion of the light emitting layer OL may be broken around the dummy layer DML. Accordingly, the light emitting layer OL may be divided into a light emitting layer portion (hereinafter, referred to as a main light emitting layer MOL) continuously disposed on the anodes ANO and the pixel defining layer 170 and a light emitting layer portion (hereinafter, referred to as a dummy light emitting layer DOL) disposed on the dummy layer DML. For example, the main light emitting layer MOL on the anodes ANO and the dummy light emitting layer DOL on the dummy layer DML may be physically separated from each other. This may be due to the dummy layer DML between the pixel defining layer 170 and the light emitting layer OL. For example, since the lower dummy layer LD of the dummy layer DML has a reverse-tapered shape (or overhang shape) whose width gradually increases as being farther from the lower surface LW of the lower dummy layer LD along the third direction DR3, the light emitting layer OL may be separated into (or spaced apart from) the main light emitting layer MOL and the dummy light emitting layer DOL by the reverse-tapered lower dummy layer LD. According to an embodiment, while the main light emitting layer MOL is electrically connected to the anodes ANO, the dummy light emitting layer DOL may not be connected to the anodes ANO. Therefore, a voltage of the anodes ANO may not be applied to the dummy light emitting layer DOL.

According to some embodiments, a portion of the main light emitting layer MOL which is adjacent to the dummy layer DML may be disposed on the pixel defining layer 170.

The light emitting layer OL will be described in more detail later.

A cathode CE (or a second electrode) of the light emitting unit 100 may be disposed on the light emitting layer OL. In some embodiments, the cathode CE may be disposed on the light emitting layer OL and may be in the shape of a layer formed over the light emitting areas ELA_1 through ELA_3 and the non-light emitting area NELA. For example, the cathode CE may cover (e.g., completely cover) the light emitting layer OL.

In some embodiments, a portion of the cathode CE may be broken (or divided). For example, at least a portion of the cathode CE may be broken around the dummy layer DML. Accordingly, the cathode CE may be divided into a cathode portion (hereinafter, referred to as a main cathode MCE) disposed on the main light emitting layer MOL to overlap the anodes ANO described above and a cathode portion (hereinafter, referred to as a dummy cathode DCE) disposed on the dummy light emitting layer DOL to overlap the dummy layer DML described above. For example, the main cathode MCE on the main light emitting layer MOL and the dummy cathode DCE on the dummy light emitting layer DOL may be physically separated (or spaced apart) from each other. This may be due to the dummy layer DML having a reverse-tapered shape as described above. According to an embodiment, while the main cathode MCE is electrically connected to a second voltage line which will be described later, the dummy cathode DCE may not be connected to the second voltage line. Therefore, a second voltage may not be applied to the dummy cathode DCE. For example, the second voltage line may be disposed, for example, under the cathode CE. The main cathode MCE may be connected to the second voltage line thereunder through a laser drilling hole (or a type of contact hole) that penetrates an insulating layer.

The cathode CE may have translucency or transparency. In case that a thickness of the cathode CE is tens to hundreds of angstroms (Å), the cathode CE may have translucency. In some embodiments, in case that the cathode CE has translucency, it may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). The cathode CE may also have transparency by including a transparent conductive oxide. In some embodiments, in case that the cathode CE has transparency, it may include tungsten oxide (WROx), titanium oxide (TiO₂), indium tin oxide (ITO), indium zinc oxide (IZO), zinc oxide (ZnO), indium tin zinc oxide (ITZO), or magnesium oxide (MgO).

The anodes ANO, the light emitting layer OL, and the cathode CE may form light emitting elements. For example, the anode ANO, the light emitting layer OL and the cathode CE overlapping the first light emitting area ELA_1 may form a first light emitting element, the anode ANO, the light emitting layer OL and the cathode CE overlapping the second light emitting area ELA_2 may form a second light emitting element, and the anode ANO, the light emitting layer OL and the cathode CE overlapping the third light emitting area ELA_3 may form a third light emitting element. Each of the first light emitting element, the second light emitting element, and the third light emitting element may emit output light LE.

Referring to FIG. 8, the output light LE finally emitted from the light emitting layer OL (e.g., the main light emitting layer MOL) may be a mixture of a first component LE1 and a second component LE2. Each of the first component LE1 and the second component LE2 in the output light LE may have a peak wavelength in the range of about 440 nm to less than about 480 nm. For example, the output light LE may be blue light.

In some embodiments, the light emitting layer OL may have a structure in which light emitting material layers overlap, for example, a tandem structure as illustrated in FIG. 8. For example, the light emitting layer OL including the main light emitting layer MOL and the dummy light emitting layer DOL may have the tandem structure described above. For example, the light emitting layer OL may include a first stack ST1 including a first light emitting material layer EML1, a second stack ST2 positioned on the first stack ST1 and including a second light emitting material layer EML2, a third stack ST3 positioned on the second stack ST2 and including a third light emitting material layer EML3, a first charge generation layer CGL1 positioned between the first stack ST1 and the second stack ST2, and a second charge generation layer CGL2 positioned between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other.

In some embodiments, the first light emitting material layer EML1, the second light emitting material layer EML2, and the third light emitting material layer EML3 may all emit light of the first color, for example, blue light. For example, each of the first light emitting material layer EML1, the second light emitting material layer EML2, and the third light emitting material layer EML3 may be a blue light emitting layer and may include an organic material.

In some embodiments, at least any one of the first light emitting material layer EML1, the second light emitting material layer EML2 and the third light emitting material layer EML3 may emit first blue light having a first peak wavelength, and at least another one of the first light emitting material layer EML1, the second light emitting material layer EML2 and the third light emitting material layer EML3 may emit second blue light having a second peak wavelength different from the first peak wavelength. For example, any one of the first light emitting material layer EML1, the second light emitting material layer EML2 and the third light emitting material layer EML3 may emit the first blue light having the first peak wavelength, and the other two of the first light emitting material layer EML1, the second light emitting material layer EML2 and the third light emitting material layer EML3 may emit the second blue light having the second peak wavelength. For example, the output light LE finally emitted from the light emitting layer OL may be a mixture of the first component LE1 and the second component LE2. For example, the first component LE1 may be the first blue light having the first peak wavelength, and the second component LE2 may be the second blue light having the second peak wavelength.

In some embodiments, any one of the first peak wavelength and the second peak wavelength may be in the range of about 440 nm to less than about 460 nm. The other one of the first peak wavelength and the second peak wavelength may be in the range of about 460 nm to about 480 nm. However, the range of the first peak wavelength and the range of the second peak wavelength are not limited thereto. For example, both the range of the first peak wavelength and the range of the second peak wavelength may include about 460 nm. In some embodiments, any one of the first blue light and the second blue light may be light of a deep blue color, and the other one of the first blue light and the second blue light may be light of a sky blue color.

According to some embodiments, the output light LE emitted from the light emitting layer OL may be blue light and may include a long wavelength component and a short wavelength component. Therefore, the light emitting layer OL may finally emit blue light having a broader emission peak as the output light LE, thereby improving color visibility at a side viewing angle compared with a conventional light emitting element that emits blue light having a sharp emission peak.

In some embodiments, each of the first light emitting material layer EML1, the second light emitting material layer EML2, and the third light emitting material layer EML3 may include a host and a dopant. The host is not limited as long as it is a commonly used material. However, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene) (MADN) may be used.

Each of the first light emitting material layer EML1, the second light emitting material layer EML2, and the third light emitting material layer EML3 which emit blue light may include, for example, a fluorescent material including any one of spiro-DPVBi, spiro-6P, distyryl-benzene (DSB), distyryl-arylene (DSA), a polyfluorene (PFO)-based polymer, and a poly(p-phenylene vinylene) (PPV)-based polymer. For another example, a phosphorescent material including an organometallic complex such as (4,6-F2ppy)2Irpic may be included.

As described above, at least one of the first light emitting material layer EML1, the second light emitting material layer EML2 and the third light emitting material layer EML3 and at least another one of the first light emitting material layer EML1, the second light emitting material layer EML2 and the third light emitting material layer EML3 emit blue light in different wavelength ranges. To emit blue light in different wavelength ranges, the first light emitting material layer EML1, the second light emitting material layer EML2 and the third light emitting material layer EML3 may include the same material, and a resonance distance may be adjusted. In another example, to emit blue light in different wavelength ranges, at least one of the first light emitting material layer EML1, the second light emitting material layer EML2 and the third light emitting material layer EML3 and at least another one of the first light emitting material layer EML1, the second light emitting material layer EML2 and the third light emitting material layer EML3 may include different materials.

However, embodiments are not limited thereto. The first light emitting material layer EML1, the second light emitting material layer EML2 and the third light emitting material layer EML3 may also all emit blue light having a peak wavelength of about 440 nm to about 480 nm and may be made of the same material.

In another example, in an embodiment, at least any one of the first light emitting material layer EML1, the second light emitting material layer EML2 and the third light emitting material layer EML3 may emit the first blue light having the first peak wavelength, another one of the first light emitting material layer EML1, the second light emitting material layer EML2 and the third light emitting material layer EML3 may emit the second blue light having the second peak wavelength different from the first peak wavelength, and the other one of the first light emitting material layer EML1, the second light emitting material layer EML2 and the third light emitting material layer EML3 may emit third blue light having a third peak wavelength different from the first peak wavelength and the second peak wavelength. In some embodiments, any one of the first peak wavelength, the second peak wavelength and the third peak wavelength may be in the range of about 440 nm to less than about 460 nm. Another one of the first peak wavelength, the second peak wavelength and the third peak wavelength may be in the range of about 460 nm to less than about 470 nm, and the other one of the first peak wavelength, the second peak wavelength and the third peak wavelength may be in the range of about 470 nm to about 480 nm.

According to some embodiments, the output light LE emitted from the light emitting layer OL may be blue light and may include a long wavelength component, a medium wavelength component and a short wavelength component. Therefore, the light emitting layer OL may finally emit blue light having a broader emission peak as the output light LE and improve color visibility at a side viewing angle.

According to the above-described embodiments, it is possible to improve light efficiency and extend the life of the display device 1 as compared with a conventional light emitting element that does not employ (or use) a tandem structure, e.g., a structure in which light emitting layers OL are stacked.

In another example, in some embodiments, at least any one of the first light emitting material layer EML1, the second light emitting material layer EML2 and the third light emitting material layer EML3 may emit light of the third color, for example, blue light, and at least another one of the first light emitting material layer EML1, the second light emitting material layer EML2 and the third light emitting material layer EML3 may emit light of the third color, for example, green light. In some embodiments, blue light emitted from at least any one of the first light emitting material layer EML1, the second light emitting material layer EML2, and the third light emitting material layer EML3 may have a peak wavelength in the range of about 440 nm to about 480 nm or about 460 nm to 480 nm. Green light emitted from at least another one of the first light emitting material layer EML1, the second light emitting material layer EML2, and the third light emitting material layer EML3 may have a peak wavelength in the range of about 510 nm to about 550 nm.

For example, any one of the first light emitting material layer EML1, the second light emitting material layer EML2 and the third light emitting material layer EML3 may be a green light emitting layer OL emitting green light, and the other two of the first light emitting material layer EML1, the second light emitting material layer EML2 and the third light emitting material layer EML3 may be blue light emitting layers OL emitting blue light. In case that the other two of the first light emitting material layer EML1, the second light emitting material layer EML2 and the third light emitting material layer EML3 are blue light emitting layers OL, peak wavelengths of blue light emitted from the two blue light emitting layers OL may be in the same range or in different ranges.

According to some embodiments, the output light LE emitted from the light emitting layer OL may be a mixture of the first component LE1 which is blue light and the second component LE2 which is green light. For example, in case that the first component LE1 is dark blue light and the second component LE2 is green light, the output light LE may be light having a sky blue color. In the above-described embodiments, the output light LE emitted from the light emitting layer OL may be a mixture of blue light and green light and may include a long wavelength component and a short wavelength component. Therefore, the light emitting layer OL may finally emit blue light having a broader emission peak as the output light LE and improve color visibility at a side viewing angle. For example, since the second component LE2 of the output light LE is green light, a green light component may be supplemented in the light provided from the display device 1 to the outside. Accordingly, the color reproducibility of the display device 1 may be improved.

In some embodiments, a green light emitting material layer among the first light emitting material layer EML1, the second light emitting material layer EML2, and the third light emitting material layer EML3 may include a host and a dopant. The host included in the green light emitting material layer is not limited as long as it is a commonly used material. However, for example, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene) (MADN) may be used.

The dopant included in the green light emitting material layer may be, for example, a fluorescent material including tris-(8-hydroyquinolato)aluminum (III) (Alq3) or may be a phosphorescent material such as Ir(ppy)3(fac tris(2-phenylpyridine)iridium), Ir(ppy)2(acac)(Bis(2-phenylpyridine)(acetylacetonate)iridium(III)) or Ir(mpyp)3(2-phenyl-4-methyl-pyridine iridium).

The first charge generation layer CGL1 may be positioned between the first stack ST1 and the second stack ST2. The first charge generation layer CGL1 may inject electric charges into each light emitting layer OL. The first charge generation layer CGL1 may control the charge balance between the first stack ST1 and the second stack ST2. The first charge generation layer CGL1 may include an n-type charge generation layer CGL11 and a p-type charge generation layer CGL12. The p-type charge generation layer CGL12 may be disposed on the n-type charge generation layer CGL11 and may be positioned between the n-type charge generation layer CGL11 and the second stack ST2.

The first charge generation layer CGL1 may have a structure in which the n-type charge generation layer CGL11 and the p-type charge generation layer CGL12 are in contact with each other. The n-type charge generation layer CGL11 may be disposed closer to an anode ANO among the anode ANO and the cathode CE. The p-type charge generation layer CGL12 may be disposed closer to the cathode CE among the anode ANO and the cathode CE. The n-type charge generation layer CGL11 supplies electrons to the first light emitting material layer EML1 adjacent to the anode ANO, and the p-type charge generation layer CGL12 supplies holes to the second light emitting material layer EML2 included in the second stack ST2. Since the first charge generation layer CGL1 is disposed between the first stack ST1 and the second stack ST2 to provide electric charges to each light emitting layer OL, luminous efficiency may be improved, and a driving voltage may be lowered.

In FIG. 6, the anode ANO corresponding to the first light emitting area ELA_1 may be defined as a first anode, the anode ANO corresponding to the second light emitting area ELA_2 may be defined as a second anode, and the anode ANO corresponding to the third light emitting area ELA_3 may be defined as a third anode. For example, the first stack ST1 may be positioned on the first anode, the second anode, and the third anode. For example, the first stack ST1 may further include a first hole transport layer HTL1, a first electron blocking layer BIL1, and a first electron transport layer ETL1.

The first hole transport layer HTL1 may be positioned on the first anode, the second anode, and the third anode. The first hole transport layer HTL1 may facilitate the transportation of holes and may include a hole transport material. The hole transport material may include a carbazole derivative such as N-phenylcarbazole or polyvinylcarbazole; a fluorene derivative; a triphenylamine derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA); N,N′-di(1-naphthyl)-N,N′-diphenylbenzidine) (NPB); or 4,4′-Cyclohexylidene bis[N,N-bis(4-methylphenyl)benzenamine] (TAPC). However, embodiments are not limited thereto.

The first electron blocking layer BIL1 may be positioned on the first hole transport layer HTL1 and may be positioned between the first hole transport layer HTL1 and the first light emitting material layer EML1. The first electron blocking layer BIL1 may include a hole transport material and a metal or a metal compound in order to prevent electrons generated by the first light emitting material layer EML1 from entering the first hole transport layer HTL1. In some embodiments, the first hole transport layer HTL1 and the first electron blocking layer BIL1 described above may be formed as a single layer in which their respective materials are mixed.

The first electron transport layer ETL1 may be positioned on the first light emitting material layer EML1 and may be positioned between the first charge generation layer CGL1 and the first light emitting material layer EML1. In some embodiments, the first electron transport layer ETL1 may include an electron transport material such as tris-(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphalene-2-yl)anthracene (ADN), or a mixture thereof. However, embodiments are not limited to the type of the electron transport material. The second stack ST2 may be positioned on the first charge generation layer CGL1 and may further include a second hole transport layer HTL2, a second electron blocking layer BIL2 and a second electron transport layer ETL2.

The second hole transport layer HTL2 may be positioned on the first charge generation layer CGL1. The second hole transport layer HTL2 may be made of the same material as the first hole transport layer HTL1 or may include one or more materials selected from the materials such as the materials included in the first hole transport layer HTL1. The second hole transport layer HTL2 may be composed of a single layer or a plurality of layers.

The second electron blocking layer BIL2 may be positioned on the second hole transport layer HTL2 and may be positioned between the second hole transport layer HTL2 and the second light emitting material layer EML2. The second electron blocking layer BIL2 may have the same material and structure as the first electron blocking layer BIL1 or may include one or more materials selected from the materials such as the materials included in the first electron blocking layer BIL1.

The second electron transport layer ETL2 may be positioned on the second light emitting material layer EML2 and may be positioned between the second charge generation layer CGL2 and the second light emitting material layer EML2. The second electron transport layer ETL2 may have the same material and structure as the first electron transport layer ETL1 or may include one or more materials selected from the materials such as the materials included in the first electron transport layer ETL1. The second electron transport layer ETL2 may be composed of a single layer or a plurality of layers.

The second charge generation layer CGL2 may be positioned on the second stack ST2 and may be positioned between the second stack ST2 and the third stack ST3.

The second charge generation layer CGL2 may have the same structure as the first charge generation layer CGL1 described above. For example, the second charge generation layer CGL2 may include an n-type charge generation layer CGL21 disposed closer to the second stack ST2 and a p-type charge generation layer CGL22 disposed closer to the cathode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 are in contact with each other. The first charge generation layer CGL1 and the second charge generation layer CGL2 may be made of different materials or the same material.

The third stack ST3 may be positioned on the second charge generation layer CGL2 and may further include a third hole transport layer HTL3 and a third electron transport layer ETL3.

The third hole transport layer HTL3 may be positioned on the second charge generation layer CGL2. The third hole transport layer HTL3 may be made of the same material as the first hole transport layer HTL1 or may include one or more materials selected from the materials such as the materials included in the first hole transport layer HTL1. The third hole transport layer HTL3 may be composed of a single layer or a plurality of layers. In case that the third hole transport layer HTL3 is composed of a plurality of layers, the layers may include different materials.

The third electron transport layer ETL3 may be positioned on the third light emitting material layer EML3 and may be positioned between the cathode CE and the third light emitting material layer EML3. The third electron transport layer ETL3 may have the same material and structure as the first electron transport layer ETL1 or may include one or more materials selected from the materials such as the materials included in the first electron transport layer ETL1. The third electron transport layer ETL3 may be composed of a single layer or a plurality of layers. In case that the third electron transport layer ETL3 is composed of a plurality of layers, the layers may include different materials.

For example, a hole injection layer may be further positioned in at least any one of the spaces between the first stack ST1 and the first anode, the second anode and the third anode, between the second stack ST2 and the first charge generation layer CGL1, and between the third stack ST3 and the second charge generation layer CGL2. The hole injection layer may facilitate the injection of holes into the first light emitting material layer EML1, the second light emitting material layer EML2 and the third light emitting material layer EML3. In some embodiments, the hole injection layer may be made of any one or more of copper phthalocyanine (CuPc), poly(3,4-ethylenedioxythiphene) (PEDOT), polyaniline (PANI), and N,N-dinaphthyl-N,N′-diphenyl benzidine (NPD), but embodiments are not limited thereto. In some embodiments, the hole injection layer may be positioned between the first stack ST1 and the first anode, the second anode and the third anode, between the second stack ST2 and the first charge generation layer CGL1, and between the third stack ST3 and the second charge generation layer CGL2.

For example, an electron injection layer may be further positioned in at least any one of the spaces between the third electron transport layer ETL3 and the cathode CE, between the second charge generation layer CGL2 and the second stack ST2, and between the first charge generation layer CGL1 and the first stack ST1. The electron injection layer may facilitate the injection of electrons and may use tris(8-hydroxyquinolino)aluminum) (Alq3), PBD, TAZ, spiro-PBD, BAlq or SAlq, but embodiments are not limited thereto. For example, the electron injection layer may be a metal halide compound, for example, any one or more of MgF₂, LiF, NaF, KF, RbF, CsF, FrF, LiI, NaI, KI, RbI, CsI, FrI and CaF₂, but embodiments are not limited thereto. The electron injection layer may also include a lanthanum material such as Yb, Sm, or Eu. In another example, the electron injection layer may include both a metal halide material and a lanthanum material such as RbI:Yb or KI:Yb. In case that the electron injection layer includes both a metal halide material and a lanthanum material, the electron injection layer may be formed by co-deposition of the metal halide material and the lanthanum material. In some embodiments, the electron injection layer may be positioned between the third electron transport layer ETL3 and the cathode CE, between the second charge generation layer CGL2 and the second stack ST2, and between the first charge generation layer CGL1 and the first stack ST1.

In some embodiments, the light emitting layer OL may not include a red light emitting material layer and thus may not emit light of the third color, for example, red light. For example, the output light LE may not include a light component having a peak wavelength in the range of about 610 nm to about 650 nm and may include only a light component having a peak wavelength in the range of about 440 nm to about 550 nm.

According to an embodiment, the light emitting layer OL may be broken (or divided) by the dummy layer DML. This may mean that at least one layer included in the light emitting layer OL, for example, the first hole transport layer HTL1, the first electron blocking layer BIL1, the first light emitting material layer EML1, the first electron transport layer ETL1, the n-type charge generation layer CGL11, the p-type charge generation layer CGL12, the second hole transport layer HTL2, the second electron blocking layer BIL2, the second light emitting material layer EML2, the second electron transport layer ETL2, the n-type charge generation layer CGL21, the p-type charge generation layer CGL22, the third hole transport layer HTL3, the third light emitting material layer EML3 and the third electron transport layer ETL3 are all broken (or divided).

According to an embodiment, the main light emitting layer MOL may include the first hole transport layer HTL1, the first electron blocking layer BIL1, the first light emitting material layer EML1, the first electron transport layer ETL1, the n-type charge generation layer CGL11, the p-type charge generation layer CGL12, the second hole transport layer HTL2, the second electron blocking layer BIL2, the second light emitting material layer EML2, the second electron transport layer ETL2, the n-type charge generation layer CGL21, the p-type charge generation layer CGL22, the third hole transport layer HTL3, the third light emitting material layer EML3, and the third electron transport layer ETL3 described above.

According to an embodiment, the dummy light emitting layer DOL may include the first hole transport layer HTL1, the first electron blocking layer BIL1, the first light emitting material layer EML1, the first electron transport layer ETL1, the n-type charge generation layer CGL11, the p-type charge generation layer CGL12, the second hole transport layer HTL2, the second electron blocking layer BIL2, the second light emitting material layer EML2, the second electron transport layer ETL2, the n-type charge generation layer CGL21, the p-type charge generation layer CGL22, the third hole transport layer HTL3, the third light emitting material layer EML3, and the third electron transport layer ETL3 described above.

Referring back to FIG. 6, the first capping layer CPL1 may be disposed on the cathode CE. The first capping layer CPL1 may improve viewing angle characteristics and increase external light emission efficiency. The first capping layer CPL1 may be commonly disposed in the first light emitting area ELA_1, the second light emitting area ELA_2, the third light emitting area ELA_3, and the non-light emitting area NELA. The first capping layer CPL1 may cover (e.g., completely cover) the cathode CE.

The first capping layer CPL1 may include at least any one of an inorganic material and an organic material having light transmitting properties. For example, the first capping layer CPL1 may be made of an inorganic layer or an organic layer TFEb or may be made of an organic layer TFEb including inorganic particles. In some embodiments, the first capping layer CPL1 may include a triamine derivative, a carbazole biphenyl derivative, an arylenediamine derivative, or an aluminum quinolium complex (Alq3). However, embodiments are not limited thereto.

In some embodiments, the first capping layer CPL1 may be disposed on the cathode CE to overlap the dummy layer DML described above. For example, since the upper dummy layer UD of the dummy layer DML has a forward-tapered shape whose width gradually decreases as being closer to the upper surface UP of the upper dummy layer UD along the third direction DR3, damage to the first capping layer CPL1 overlapping the dummy layer DML may be minimized. For example, the first capping layer CPL1 may not be broken (or divided) by the dummy layer DML. Accordingly, the first capping layer CPL1 may cover broken portions of the light emitting layer OL and/or broken portions of the cathode CE.

The thin-film encapsulation layer TFE of the light emitting unit 100 may be disposed on the first capping layer CPL1. The thin-film encapsulation layer TFE may protect elements positioned under the thin-film encapsulation layer TFE from external foreign substances such as moisture. The thin-film encapsulation layer TFE may be commonly disposed in the first light emitting area ELA_1, the second light emitting area ELA_2, the third light emitting area ELA_3, and the non-light emitting area NELA. The thin-film encapsulation layer TFE may cover (e.g., completely cover) the first capping layer CPL1.

The thin-film encapsulation layer TFE may include a lower inorganic layer TFEa, an organic layer TFEb, and an upper inorganic layer TFEc sequentially stacked on the first capping layer CPL1.

The lower inorganic layer TFEa may cover (e.g., completely cover) the first capping layer CPL1 in the display area DA to cover the first light emitting element, the second light emitting element and the third light emitting element.

The organic layer TFEb may be disposed on the lower inorganic layer TFEa to cover the first light emitting element, the second light emitting element and the third light emitting element.

The upper inorganic layer TFEc may be disposed on the organic layer TFEb to cover (e.g., completely cover) the organic layer TFEb.

In some embodiments, each of the lower inorganic layer TFEa and the upper inorganic layer TFEc may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), or lithium fluoride, but embodiments are not limited thereto.

In some embodiments, the organic layer TFEb may be made of acrylic resin, methacrylic resin, polyisoprene, vinyl resin, epoxy resin, urethane resin, cellulose resin, or perylene resin, but embodiments are not limited thereto.

In some embodiments, the thin-film encapsulation layer TFE may be disposed on the first capping layer CPL1 to overlap the dummy layer DML described above. For example, since the upper dummy layer UD of the dummy layer DML has a forward-tapered shape whose width gradually decreases as being closer to the upper surface UP of the upper dummy layer UD along the third direction DR3, damage to the thin-film encapsulation layer TFE overlapping the dummy layer DML may be minimized. For example, the thin-film encapsulation layer TFE may not be broken (or divided) by the dummy layer DML. Accordingly, the thin-film encapsulation layer TFE may cover broken portions of the light emitting layer OL and/or broken portions of the cathode CE.

The wavelength conversion member WC of the light emitting unit 100 may be disposed on the thin-film encapsulation layer TFE. The wavelength conversion member WC may emit red light, green light, and blue light by converting the wavelength of light emitted from the light emitting element layer EML.

The wavelength conversion member WC may include a first wavelength conversion layer TPL, a second wavelength conversion layer WCL1, a third wavelength conversion layer WCL2, the bank member BK, and a second capping layer CPL2.

The bank member BK may define spaces in which wavelength conversion layers to be described later are disposed. The bank member BK may surround the first wavelength conversion layer TPL, the second wavelength conversion layer WCL1, and the third wavelength conversion layer WCL2 in plan view. The bank member BK may overlap the non-light emitting area NELA of the light emitting unit 100 and the light blocking area BA of the color filter unit 300. The bank member BK may not overlap the light emitting areas ELA_1 through ELA_3 of the light emitting unit 100 and the light transmitting areas TA_1 through TA_3 of the color filter unit 300.

In some embodiments, the bank member BK may include a photocurable organic material or a photocurable organic material including a light blocking material. However, embodiments are not limited thereto.

The wavelength conversion member WC of the light emitting unit 100 may include the first wavelength conversion layer TPL overlapping the first light transmitting area TA_1, the second wavelength conversion layer WCL1 overlapping the second light transmitting area TA_2, and the third wavelength conversion layer WCL2 overlapping the third light transmitting area TA_3.

The first wavelength conversion layer TPL may be disposed in a space defined by the bank member BK and may overlap the first light emitting area ELA_1 and the first light transmitting area TA_1 in the third direction DR3. The first wavelength conversion layer TPL may contact (e.g., directly contact) the second capping layer CPL2 and the bank member BK.

The first wavelength conversion layer TPL may be a light transmitting pattern that transmits incident light. For example, the output light LE provided by the first light emitting element may be blue light as described above and may pass through the first wavelength conversion layer TPL and a first filtering pattern area 321a of the first color filter 321 to exit the display device 1. For example, first output light L1 emitted from the first light emitting area ELA_1 to the outside through the first light transmitting area TA_1 may be blue light.

The first wavelength conversion layer TPL may include a base resin 330 and light scatterers 331.

The base resin 330 may be made of an organic material having high light transmittance. In some embodiments, the base resin 330 may include an organic material such as epoxy resin, acrylic resin, cardo resin, or imide resin. However, embodiments are not limited thereto.

The light scatterers 331 may have a refractive index different from that of the base resin 330 and may form an optical interface with the base resin 330. The light scatterers 331 may be light scattering particles. The light scatterers 331 may scatter incident light in random directions regardless of the incident direction of the incident light without substantially converting the wavelength of the incident light passing through the light transmitting area TA_1.

The light scatterers 331 may be materials that scatter at least a portion of transmitted light and may include metal oxide particles or organic particles. In some embodiments, the light scatterers 331 may include titanium oxide (TiO₂), zirconium oxide (ZrO₂), aluminum oxide (Al₂O₃), indium oxide (In₂O₃), zinc oxide (ZnO) or tin oxide (SnO₂) as the metal oxide and may include acrylic resin or urethane resin as the organic particles, but embodiments are not limited thereto.

The second wavelength conversion layer WCL1 may be disposed in a space defined by the bank member BK and may overlap the second light emitting area ELA_2 and the second light transmitting area TA_2 in the third direction DR3. The second wavelength conversion layer WCL1 may contact (e.g., directly contact) the second capping layer CPL2 and the bank member BK.

The second wavelength conversion layer WCL1 may be a wavelength converting pattern that converts or shifts a peak wavelength of incident light into another specific peak wavelength and outputs light having the specific peak wavelength. For example, the output light LE provided by the second light emitting element may be blue light as described above and may be converted into green light having a peak wavelength in the range of about 510 nm to about 550 nm as it passes through the second wavelength conversion layer WCL1 and a second filtering pattern area 322a of the second color filter 322. Accordingly, the green light may be emitted to the outside of the display device 1. For example, second output light L2 emitted from the second light emitting area ELA_2 to the outside through the second light transmitting area TA_2 may be green light.

The second wavelength conversion layer WCL1 may include a base resin 330, light scatterers 331 dispersed in the base resin 330, and first wavelength shifters 332 dispersed in the base resin 330.

The first wavelength shifters 332 may convert or shift a peak wavelength of incident light into another specific peak wavelength. The first wavelength shifters 332 may convert the output light LE, which is blue light provided by the second light emitting element, into green light having a single peak wavelength in the range of about 510 nm to about 550 nm and output the green light.

In some embodiments, the first wavelength shifters 332 may be quantum dots, quantum rods, or phosphors. However, embodiments are not limited thereto. For descriptive convenience, a case where the first wavelength shifters 332 are quantum dots will be described below. The quantum dots may be particulate materials that emit light of a specific color in case that electrons transit from a conduction band to a valence band. The quantum dots may be semiconductor nanocrystalline materials. The quantum dots may have a specific band gap according to their composition and size. Thus, the quantum dots may absorb light and then emit light having a unique wavelength. Examples of semiconductor nanocrystals of the quantum dots include group IV nanocrystals, group II-VI compound nanocrystals, group III-V compound nanocrystals, group IV-VI nanocrystals, and combinations thereof.

The group II-VI compounds may be selected from binary compounds selected from CdSe, CdTe, ZnS, ZnSe, ZnTe, ZnO, HgS, HgSe, HgTe, MgSe, MgS and mixtures thereof; ternary compounds selected from InZnP, AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and quaternary compounds selected from HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compounds may be selected from binary compounds selected from GaN, GaP, GaAs, GaSb, AlN, AIP, AlAs, AlSb, InN, InP, InAs, InSb and mixtures thereof; ternary compounds selected from GaNP, GaNAs, GaNSb, GaPAs, GaPSb, AlNP, AlNAs, AlNSb, AlPAs, AlPSb, InGaP, InNP, InAIP, InNAs, InNSb, InPAs, InPSb, GaAlNP and mixtures thereof; and quaternary compounds selected from GaAlNAs, GaAINSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

The group IV-VI compounds may be selected from binary compounds selected from SnS, SnSe, SnTe, PbS, PbSe, PbTe and mixtures thereof; ternary compounds selected from SnSeS, SnSeTe, SnSTe, PbSeS, PbSeTe, PbSTe, SnPbS, SnPbSe, SnPbTe and mixtures thereof; and quaternary compounds selected from SnPbSSe, SnPbSeTe, SnPbSTe and mixtures thereof. The group IV elements may be selected from silicon (Si), germanium (Ge), and a mixture thereof. The group IV compounds may be binary compounds selected from silicon carbide (SIC), silicon germanium (SiGe), and a mixture thereof.

For example, the binary, ternary or quaternary compounds may be present in particles at a uniform concentration or may be present in the same particles at partially different concentrations. For example, they may have a core/shell structure in which one quantum dot surrounds another quantum dot. An interface between the core and the shell may have a concentration gradient in which the concentration of an element present in the shell is reduced toward the center.

In some embodiments, the quantum dots may have a core-shell structure that includes a core containing the above-described nanocrystal and a shell surrounding the core. The shell of each quantum dot may function as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of an element present in the shell is reduced toward the center. The shell of each quantum dot may be, for example, a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ or NiO or a ternary compound such as MgAl₂O₄, CoFe₂O₄, NiFe₂O₄ or CoMn₂O₄. However, embodiments are not limited thereto.

For example, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb. However, embodiments are not limited thereto.

Light emitted from the first wavelength shifters 332 may have a full width of half maximum (FWHM) of an emission wavelength spectrum of about 45 nm or less, about 40 nm or less, or about 30 nm or less. Therefore, the color purity and color reproducibility of the display device 1 may be further improved. For example, the light emitted from the first wavelength shifters 332 may be radiated in various directions regardless of the incident direction of incident light. Therefore, the lateral visibility of the second color displayed in the second light transmitting area TA_2 may be improved.

A portion of the output light LE provided by the second light emitting element may be transmitted through the second wavelength conversion layer WCL1 without being converted into green light by the first wavelength shifters 332. Of the output light LE, a component incident on the second filtering pattern area 322a of the second color filter 322 without being wavelength-converted by the second wavelength conversion layer WCL1 may be blocked by the second filtering pattern area 322a. For example, green light into which the output light LE has been converted by the second wavelength conversion layer WCL1 may be transmitted through the second filtering pattern area 322a and then emitted to the outside. For example, the second output light L2 emitted to the outside of the display device 1 through the second light transmitting area TA_2 may be green light.

The third wavelength conversion layer WCL2 may be disposed in a space defined by the bank member BK and may overlap the third light emitting area ELA_3 and the third light transmitting area TA_3 in the third direction DR3. The third wavelength conversion layer WCL2 may contact (e.g., directly contact) the second capping layer CPL2 and the bank member BK.

The third wavelength conversion layer WCL2 may be a wavelength converting pattern that converts or shifts a peak wavelength of incident light into another specific peak wavelength and outputs light having the specific peak wavelength. For example, the output light LE provided by the third light emitting element may be blue light as described above and may be converted into red light having a peak wavelength in the range of about 610 nm to about 650 nm as it passes through the third wavelength conversion layer WCL2 and a third filtering pattern area 323a of the third color filter 323. Accordingly, the red light may be emitted to the outside of the display device 1. For example, third output light L3 emitted from the third light emitting area ELA_3 to the outside through the third light transmitting area TA_3 may be red light.

The third wavelength conversion layer WCL2 may include a base resin 330, light scatterers 331 dispersed in the base resin 330, and second wavelength shifters 333 dispersed in the base resin 330.

The second wavelength shifters 333 may convert or shift a peak wavelength of incident light to another specific peak wavelength. The second wavelength shifters 333 may convert the output light LE, which is blue light provided by the third light emitting element, into red light having a single peak wavelength in the range of about 610 nm to about 650 nm and output the red light. In some embodiments, the second wavelength shifters 333 may be quantum dots, quantum rods, or phosphors. However, embodiments are not limited thereto. In case that the second wavelength shifters 333 are quantum dots, they may have substantially the same composition as the above-described first wavelength shifters 332 in case that the first wavelength shifters 332 are quantum dots. Therefore, a description of the second wavelength shifters 333 will be omitted for descriptive convenience.

A portion of the output light LE provided by the third light emitting element may be transmitted through the third wavelength conversion layer WCL2 without being converted into red light by the second wavelength shifters 333. Of the output light LE, a component incident on the third filtering pattern area 323a of the third color filter 323 without being wavelength-converted by the third wavelength conversion layer WCL2 may be blocked by the third filtering pattern area 323a. For example, red light into which the output light LE has been converted by the third wavelength conversion layer WCL2 may be transmitted through the third filtering pattern area 323a and then emitted to the outside. For example, the third output light L3 emitted to the outside of the display device 1 through the third light transmitting area TA_3 may be red light.

The color filter unit 300 may be disposed on the wavelength conversion member WC of the light emitting unit 100. The color filter unit 300 may have a structure in which a second substrate 310 and the color filter member 320 are sequentially stacked to the second side in the third direction DR3.

The color filter unit 300 will now be described in detail with reference to FIGS. 9 through 11 in addition to FIG. 6.

The second substrate 310 of the color filter unit 300 may function as a base of the color filter unit 300. The second substrate 310 may be made of a light transmitting material. The second substrate 310 may be a glass substrate or a plastic substrate. In case that the second substrate 310 is a plastic substrate, it may have flexibility. In some embodiments, in case that the second substrate 310 is a plastic substrate, it may include polyimide. However, embodiments are not limited thereto. Since the light emitting unit 100 and the color filter unit 300 face each other in the third direction DR3 as described above, the first substrate 110 of the light emitting unit 100 and the second substrate 310 of the color filter unit 300 may face each other in the third direction DR3.

The color filter member 320 of the color filter unit 300 may be disposed between the second substrate 310 and the filler 500. The color filter member 320 may include filtering pattern areas and a light blocking pattern portion BM. The light blocking pattern portion BM may surround the filtering pattern areas. The filtering patterns of the color filter member 320 may define light transmitting areas of the color filter unit 300, and the light blocking pattern portion BM may define the light blocking area BA of the color filter unit 300.

The color filter member 320 may include the first color filter 321, the second color filter 322, and the third color filter 323 as illustrated in FIGS. 6 and 9 through 11. The first color filter 321 may absorb both the second light and the third light except for the first light, the second color filter 322 may absorb both the first light and the third light except for the second light, and the third color filter 323 may absorb both the first light and the second light except for the third light. For example, the first color filter 321 may transmit the first light, the second color filter 322 may transmit the second light, and the third color filter 323 may transmit the third light.

In some embodiments, the first color filter 321 may be a blue color filter and may include a blue colorant. As used herein, the term “colorant” is a concept encompassing both a dye and a pigment. The first color filter 321 may include a base resin, and the blue colorant may be dispersed in the base resin. In some embodiments, the second color filter 322 may be a green color filter and may include a green colorant. The second color filter 322 may include a base resin, and the green colorant may be dispersed in the base resin. In some embodiments, the third color filter 323 may be a red color filter and may include a red colorant. The third color filter 323 may include a base resin, and the red colorant may be dispersed in the base resin.

The first color filter 321 may include the first filtering pattern area 321a and a first light blocking pattern area 321b surrounding the first filtering pattern area 321a. The second color filter 322 may include the second filtering pattern area 322a and a second light blocking pattern area 322b surrounding the second filtering pattern area 322a. The third color filter 323 may include the third filtering pattern area 323a and a third light blocking pattern area 323b surrounding the third filtering pattern area 323a. For example, the first filtering pattern area 321a of the first color filter 321 may overlap the first light transmitting area TA_1, and the first light blocking pattern area 321b of the first color filter 321 may surround the first filtering pattern area 321a overlapping the first light transmitting area TA_1. However, the first light blocking pattern area 321b of the first color filter 321 may not overlap the second light transmitting area TA_2 and the third light transmitting area TA_3 and may overlap the light blocking area BA. The second filtering pattern area 322a of the second color filter 322 may overlap the second light transmitting area TA_2, and the second light blocking pattern area 322b of the second color filter 322 may surround the second filtering pattern area 322a overlapping the second light transmitting area TA_2. However, the second light blocking pattern area 322b of the second color filter 322 may not overlap the first light transmitting area TA_1 and the third light transmitting area TA_3 and may overlap the light blocking area BA. The third filtering pattern area 323a of the third color filter 323 may overlap the third light transmitting area TA_3, and the third light blocking pattern area 323b of the third color filter 323 may surround the third filtering pattern area 323a overlapping the third light transmitting area TA_3. However, the third light blocking pattern area 323b of the third color filter 323 may not overlap the first light transmitting area TA_1 and the second light transmitting area TA_2 and may overlap the light blocking area BA. For example, the filtering pattern areas of the color filter member 320 may include the first filtering pattern area 321a of the first color filter 321, the second filtering pattern area 322a of the second color filter 322 and the third filtering pattern area 323a of the third color filter 323, and the light blocking pattern portion BM may have a structure in which the first light blocking pattern area 321b of the first color filter 321, the second light blocking pattern area 322b of the second color filter 322, and the third light blocking pattern area 323b of the third color filter 323 are stacked.

The first filtering pattern area 321a of the first color filter 321 may function as a blocking filter that blocks red light and green light. For example, the first filtering pattern area 321a may transmit the first light (e.g., blue light) and block or absorb the second light (e.g., green light) and the third light (e.g., red light).

The second filtering pattern area 322a of the second color filter 322 may function as a blocking filter that blocks blue light and red light. For example, the second filtering pattern area 322a may transmit the second light (e.g., green light) and block or absorb the first light (e.g., blue light) and the third light (e.g., red light).

The third filtering pattern area 323a of the third color filter 323 may function as a blocking filter that blocks blue light and green light. For example, the third filtering pattern area 323a may transmit the third light (e.g., red light) and block or absorb the first light (e.g., blue light) and the second light (e.g., green light).

In some embodiments, the light blocking pattern portion BM may have a structure in which the first light blocking pattern area 321b, the third light blocking pattern area 323b, and the second light blocking pattern area 322b are sequentially stacked in the third direction DR3. However, embodiments are not limited thereto. For example, the light blocking pattern portion BM may not be composed of the color filters 321 through 323 described above, but may be formed of an organic light blocking material, e.g., may be formed by coating and exposing an organic light blocking material. For descriptive convenience, a case where the light blocking pattern portion BM has a structure in which the first light blocking pattern area 321b, the third light blocking pattern area 323b, and the second light blocking pattern area 322b are sequentially stacked in the third direction DR3 will be described below. The light blocking pattern portion BM may absorb all of the first light, the second light, and the third light through the above-described configuration.

The filler 500 may be interposed between the light emitting unit 100 and the color filter unit 300 to fill the space between the light emitting unit 100 and the color filter unit 300 as described above. For example, in some embodiments, the filler 500 may contact (e.g., directly contact) the second capping layer CPL2 of the light emitting unit 100 and the color filter member 320 of the color filter unit 300. However, embodiments are not limited thereto.

In some embodiments, the filler 500 may be made of a material whose extinction coefficient is substantially zero. A refractive index and an extinction coefficient may be correlated, and the extinction coefficient may decrease as the refractive index decreases. For example, in case that the refractive index is about 1.7 or less, the extinction coefficient may converge to substantially zero. In some embodiments, the filler 500 may be made of a material having a refractive index of about 1.7 or less. Accordingly, light provided by the self-light emitting elements may be prevented from being absorbed by the filler 500 as it passes through the filler 500, or the absorption of the light by the filler 500 may be minimized. In some embodiments, the filler 500 may be made of an organic material having a refractive index of about 1.4 to about 1.6.

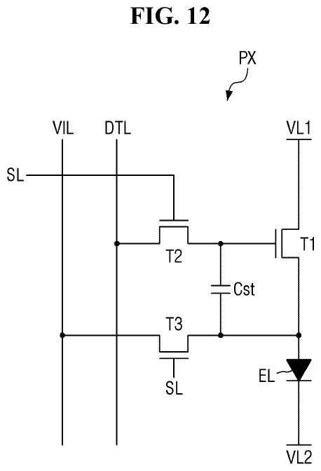

FIG. 12 is a schematic diagram of an equivalent circuit of a pixel circuit of the display device 1 according to an embodiment.

Referring to FIG. 12, a pixel PX of the display device 1 according to an embodiment may include a light emitting diode EL, transistors T1 through T3, and a storage capacitor Cst.

The light emitting diode EL may emit light according to a current supplied through a first transistor T1. The light emitting diode EL may include a first electrode (e.g., an anode), a second electrode (e.g., a cathode), and at least one light emitting element disposed between them. The light emitting element may emit light in a specific wavelength range in response to electrical signals received from the first electrode and the second electrode.

An end of the light emitting diode EL may be connected to a source electrode of the first transistor T1, and another end may be connected to a second voltage line VL2 to which a low potential voltage (e.g., a second power supply voltage) lower than a high potential voltage (e.g., a first power supply voltage) of a first voltage line VL1 is supplied.

The first transistor T1 may adjust a current flowing from the first voltage line VL1, to which the first power supply voltage is supplied, to the light emitting diode EL according to a voltage difference between a gate electrode and the source electrode. For example, the first transistor T1 may be a driving transistor for driving the light emitting diode EL. The first transistor T1 may have the gate electrode connected to a source electrode of a second transistor T2, the source electrode connected to the first electrode of the light emitting diode EL, and a drain electrode connected to the first voltage line VL1 to which the first power supply voltage is applied.

The second transistor T2 may be turned on by a scan signal of a scan line SL to connect a data line DTL to the gate electrode of the first transistor T1. The second transistor T2 may have a gate electrode connected to the scan line SL, the source electrode connected to the gate electrode of the first transistor T1, and a drain electrode connected to the data line DTL.

A third transistor T3 may be turned on by the scan signal of the scan line SL to connect an initialization voltage line VIL to the end of the light emitting diode EL. The third transistor T3 may have a gate electrode connected to the scan line SL, a drain electrode connected to the initialization voltage line VIL, and a source electrode connected to the end of the light emitting diode EL or the source electrode of the first transistor T1.

In an embodiment, the source electrode and the drain electrode of each of the transistors T1 through T3 are not limited to the above description, and the opposite may also be the case. Each of the transistors T1 through T3 may be formed as a thin-film transistor. Although a case where each of the transistors T1 through T3 is an N-type metal oxide semiconductor field effect transistor (MOSFET) has been described in FIG. 12, embodiments are not limited thereto. For example, each of the transistors T1 through T3 may also be formed as a P-type MOSFET, or some of them may be formed as N-type MOSFETs, and the other may be formed as a P-type MOSFET.

The storage capacitor Cst may be formed between the gate electrode and the source electrode of the first transistor T1. The storage capacitor Cst may store a difference voltage between a gate voltage and a source voltage of the first transistor T1.

In the embodiment of FIG. 12, the gate electrodes of the second transistor T2 and the third transistor T3 may be connected to the same scan line SL. Therefore, the second transistor T2 and the third transistor T3 are simultaneously turned on by a scan signal transmitted from the same scan line. However, embodiments are not limited thereto. The gate electrode of the second transistor T2 may also be connected to any one scan line SL, and the gate electrode of the third transistor T3 may be connected to another scan line SL different from the above scan line SL.

In some embodiments, the pixel PX of FIG. 12 may include any one of the first through third light emitting areas ELA_1 through ELA_3 of FIG. 4 described above. For example, any one of three pixels PX may include the first light emitting area ELA_1, another one of the three pixels PX may include the second light emitting area ELA_2, and the other one of the pixels PX may include the third light emitting area ELA_3.

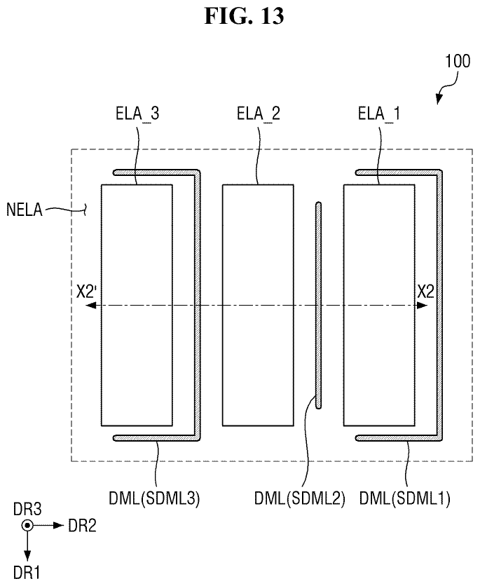

FIG. 13 is another schematic plan view of area A1 of FIG. 3, and a schematic plan view of a light emitting unit and a dummy layer DML included in the display device of FIG. 3.

A display device of FIG. 13 is different from the display device of FIG. 4 described above in the positions of light emitting areas, the shapes of the light emitting areas, the position of the dummy layer DML, and the shape of the dummy layer DML. Therefore, these differences will be described as follows.

As illustrated in FIG. 13, a first light emitting area ELA_1, a second light emitting area ELA_2, and a third light emitting area ELA_3 may be arranged in a line along the reverse of the second direction DR2 (hereinafter, referred to as a second reverse direction). For example, the first color filter 321 described above may be disposed in the first light emitting area ELA_1, the second color filter 322 described above may be disposed in the second light emitting area ELA_2, and the third color filter 323 described above may be disposed in the third light emitting area ELA_3.

The dummy layer DML may include a first sub-dummy layer SDML1, a second sub-dummy layer SDML2, and a third sub-dummy layer SDML3.

The first sub-dummy layer SDML1 may be disposed around the first light emitting area ELA_1 to face three surfaces of the first light emitting area ELA_1. The first sub-dummy layer SDML1 may have, for example, a ‘]’ shape.

The second sub-dummy layer SDML2 may be disposed between the first light emitting area ELA_1 and the second light emitting area ELA_2.

The third sub-dummy layer SDML3 may be disposed around the third light emitting area ELA_3 to face three surfaces of the third light emitting area ELA_3. At least a portion of the third sub-dummy layer SDML3 may be disposed between the third light emitting area ELA_3 and the second light emitting area ELA_2. The third sub-dummy layer SDML3 may have, for example, a ‘]’ shape.

A cross-sectional view taken along line X2-X2′ of FIG. 13 may be the same as the cross-sectional view of FIG. 6 described above.

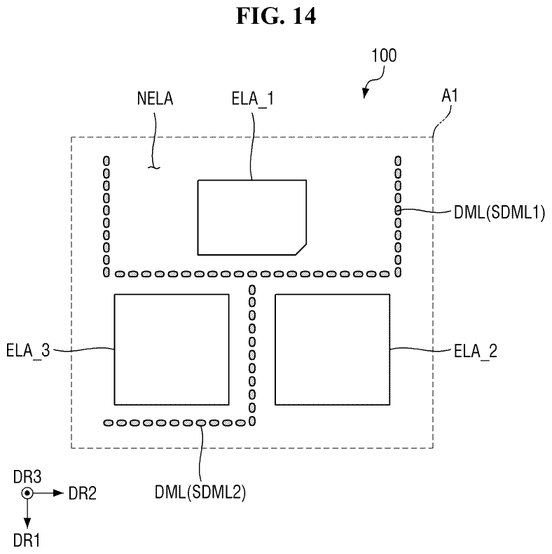

FIG. 14 is another schematic plan view of area A1 of FIG. 3, and a schematic plan view of a light emitting unit and a dummy layer DML included in the display device of FIG. 3.

A display device of FIG. 14 is different from the display device of FIG. 4 described above in the shape of the dummy layer DML. Therefore, this difference will be described as follows.

As illustrated in FIG. 14, the dummy layer DML may have a dotted shape. For example, a first sub-dummy layer SDML1 may be disposed in a dotted shape around a first light emitting area ELA_1, and a second sub-dummy layer SDML2 may be disposed in a dotted shape around a third light emitting area ELA_3.

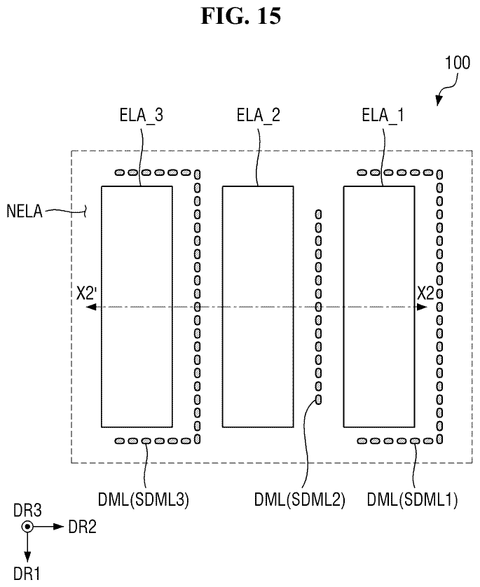

FIG. 15 is another schematic plan view of area A1 of FIG. 3, and a schematic plan view of a light emitting unit and a dummy layer DML included in the display device of FIG. 3.

A display device of FIG. 15 is different from the display device of FIG. 13 described above in the shape of the dummy layer DML. Therefore, this difference will be described as follows.

As illustrated in FIG. 15, the dummy layer DML may have a dotted shape. For example, a first sub-dummy layer SDML1 may be disposed in a dotted shape around a first light emitting area ELA_1, and a second sub-dummy layer SDML2 may be disposed in a dotted shape between the first light emitting area ELA_1 and a second light emitting area ELA_2. A third sub-dummy layer SDML3 may be disposed in a dotted shape around a third light emitting area ELA_3.

The dotted dummy layer DML may be more effective in preventing lateral leakage current in display devices having fine pixels, such as augmented reality (AR) and virtual reality (VR) display devices. For example, since greater resistance is generated in a current path between adjacent pixels by the dotted dummy layer DML, the dotted dummy layer DML may more effectively reduce the lateral leakage current in display devices having a fine pixel structure in which a distance between adjacent pixels is considerably short.

FIGS. 16 through 22 are schematic cross-sectional views for explaining a method of fabricating a display device according to an embodiment. For example, FIGS. 16 through 22 are schematic cross-sectional views for explaining a method of fabricating the display device illustrated in FIG. 7 described above.

First, as illustrated in FIG. 16, a substrate 110 on which anodes ANO are disposed may be prepared.

Next, as illustrated in FIG. 17, a pixel defining layer 170 may be disposed on the anodes ANO. For example, the pixel defining layer 170 may be disposed in a non-light emitting area NELA to overlap edge portions of the anodes ANO.

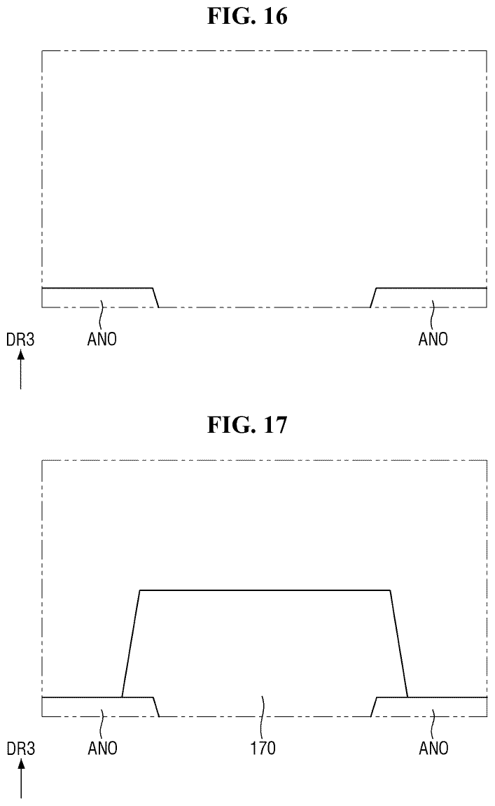

Next, as illustrated in FIG. 18, an inorganic material which is a raw material for a dummy layer DML is applied to the entire surface of the substrate 110 including the pixel defining layer 170 and the anodes ANO and then cured to form an organic material layer DM_S which covers the entire surface of the substrate 110 including the pixel defining layer 170 and the anodes ANO. For example, the organic material may be a negative type organic material. Therefore, the organic material layer DM_S made of the organic material may also include a negative type organic material. The process of curing the organic material described above may be performed, for example, by a soft bake process.

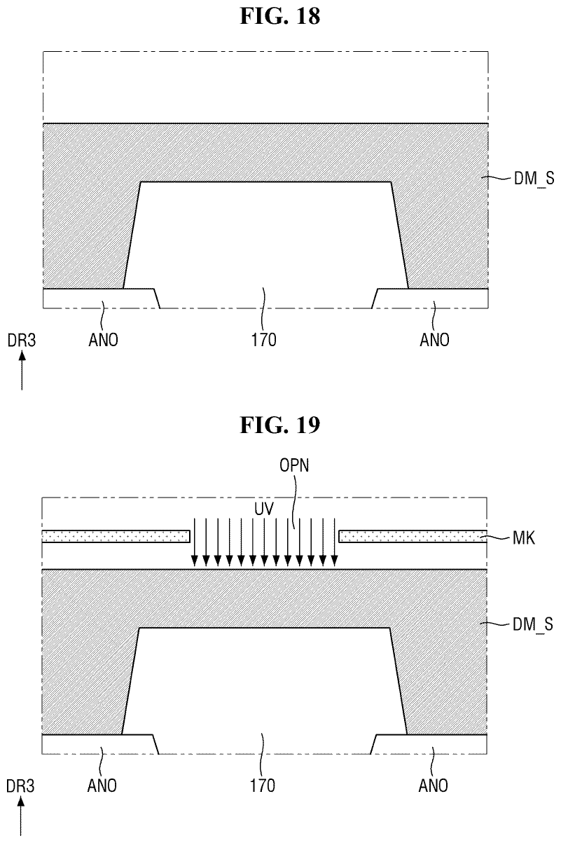

Next, as illustrated in FIG. 19, an exposure process may be performed on the organic material layer DM_S. For example, a mask MK may be placed above the organic material layer DM_S. The mask MK may have an opening OPN that exposes an organic material layer portion on the pixel defining layer 170. In case that ultraviolet light UV is irradiated through the mask MK placed above the organic material layer DM_S, the ultraviolet light UV may be irradiated only to the organic material layer portion exposed through the opening OPN of the mask MK. Accordingly, the organic material layer DM_S may include an exposed portion and an unexposed portion.

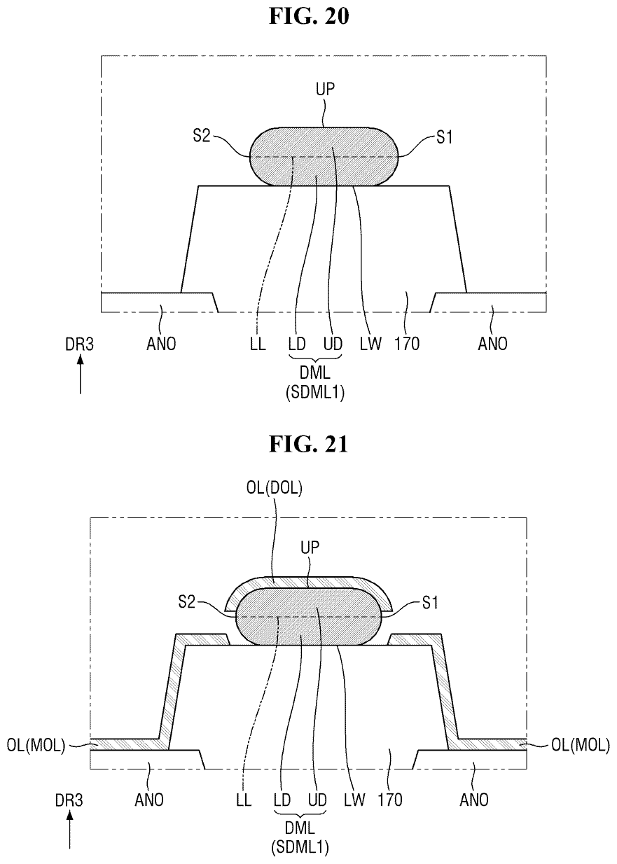

Next, a development process may be performed on the exposed organic material layer DM_S. For example, in case that a developer comes into contact with the organic material layer DM_S on which the exposure process has been performed, the unexposed portion of the organic material layer DM_S may be removed by the developer, thereby forming the dummy layer DML as illustrated in FIG. 20. For example, only the exposed portion of the organic material layer DM_S may remain. After the development process, a hard bake process may be additionally performed on the organic material layer DM_S.

Next, as illustrated in FIG. 21, a light emitting layer OL may be deposited on the substrate 110 including the dummy layer DML. For example, since edge portions of a lower dummy layer LD included in the dummy layer DML have a reverse-tapered shape, the light emitting layer OL may be broken (or divided) around the dummy layer DML. Accordingly, the light emitting layer OL may be divided into a main light emitting layer MOL on the anodes ANO and a dummy light emitting layer DOL on the dummy layer DML.

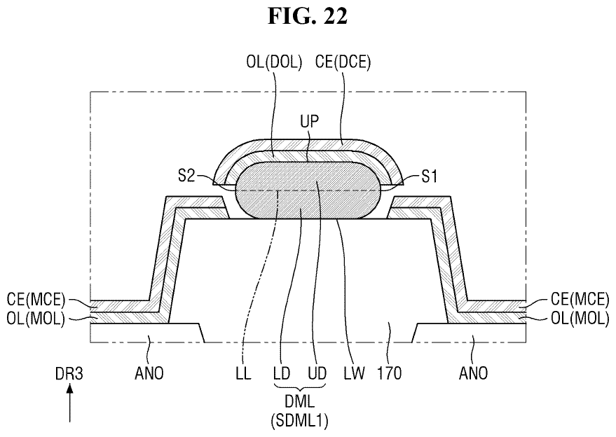

Next, as illustrated in FIG. 22, a cathode CE may be disposed on the light emitting layer OL. For example, since the edge portions of the lower dummy layer LD included in the dummy layer DML have a reverse-tapered shape, the cathode CE may be broken around the dummy layer DML. Accordingly, the cathode CE may be divided into a main cathode MCE on the main light emitting layer MOL and a dummy cathode DCE on the dummy layer DML.

Next, as illustrated in FIG. 7 described above, a first capping layer CPL1, a lower inorganic layer TFEa, an organic layer TFEb, and an upper inorganic layer TFEc may be sequentially formed on the cathode CE.

Next, as illustrated in FIG. 6 described above, a wavelength conversion member WC may be disposed on the upper inorganic layer TFEc.

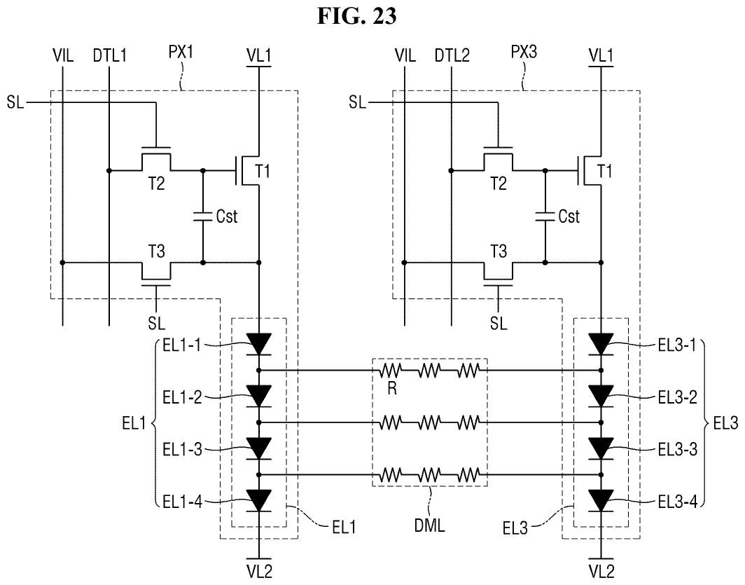

FIG. 23 is a schematic diagram for explaining the effect of preventing lateral leakage current between adjacent pixels by a dummy layer DML in a display device according to an embodiment.

As illustrated in FIG. 23, a first pixel PX1 may be a pixel including the first light emitting area ELA_1 described above, and a third pixel PX3 may be a pixel including the third light emitting area ELA_3 described above. The first pixel PX1 and the third pixel PX3 may be adjacent to each other. For example, the first pixel PX1 and the third pixel PX3 may be pixels included in one unit pixel or may be pixels included in different unit pixels. For example, the first pixel PX1 may be any one of three pixels included in a first unit pixel, and the third pixel PX3 may be any one of three pixels included in a third unit pixel. For example, the second transistor T2 of the first pixel PX1 may be turned on by the scan signal of the scan line SL to connect a first data line DTL1 to the gate electrode of the first transistor T1 of the first pixel PX1. The second transistor T2 of the third pixel PX3 may be turned on by the scan signal of the scan line SL to connect a second data line DTL2 to the gate electrode of the first transistor T1 of the third pixel PX3.

For example, a first light emitting diode EL1 of the first pixel PX1 may include light emitting elements EL1-1 through EL1-4 connected in series between a first transistor T1 provided in the first pixel PX1 and a second voltage line VL2, and a third light emitting diode EL3 of the third pixel PX3 may include light emitting elements EL3-1 through EL3-4 connected in series between a transistor T1 included in the third pixel PX3 and a second voltage line VL2. In FIG. 23, as an example, the first light emitting diode EL1 and the third light emitting diode EL3 are illustrated as 4-tandem light emitting diodes, each including four light emitting elements.

As described above, since a light emitting layer OL is broken (or divided) between the first light emitting area ELA_1 and a second light emitting area ELA_2 by the dummy layer DML, a large resistance may be generated between the light emitting elements EL1-1 through EL1-4 of the first light emitting diode EL1 and the light emitting elements EL3-1 through EL3-4 of the third light emitting diode EL3. For example, an equivalent circuit may be established as if a large number of resistors R were disposed between the first pixel PX1 including the first light emitting area ELA_1 and the third pixel PX3 including the third light emitting area ELA_3. Accordingly, lateral leakage current between the first pixel PX1 and the third pixel PX3 may be minimized. For example, the lateral leakage current between the first pixel PX1 providing blue light and the third pixel PX3 providing red light may be minimized. Therefore, at a time in case that the third light emitting diode EL3 of the third pixel PX3 is turned on and the first light emitting diode EL1 of the first pixel PX1 is turned off, the problem that the first light emitting diode EL1 of the first pixel PX1 is turned on by the lateral leakage current from the turned-on third pixel PX3 may be solved. In case that the lateral leakage current from the third pixel PX3 is provided to the first pixel PX1 at a time in case that the third pixel PX3 is turned on, for example, red light from the third pixel PX3 and blue light from the pixel PX1 may be mixed with each other. For example, due to the lateral leakage current from the third pixel PX3, sufficient current (e.g., driving current) may not be supplied to the third light emitting diode EL3 of the third pixel PX3, thereby deteriorating the color purity of the red light. However, in case that the light emitting layer OL is partially broken (or divided) by the dummy layer DML disposed between adjacent pixels as in the embodiment, the lateral leakage current is minimized due to increased resistance. Accordingly, the color mixing phenomenon and the color purity deterioration phenomenon may be prevented, thereby improving the image quality of the display device.

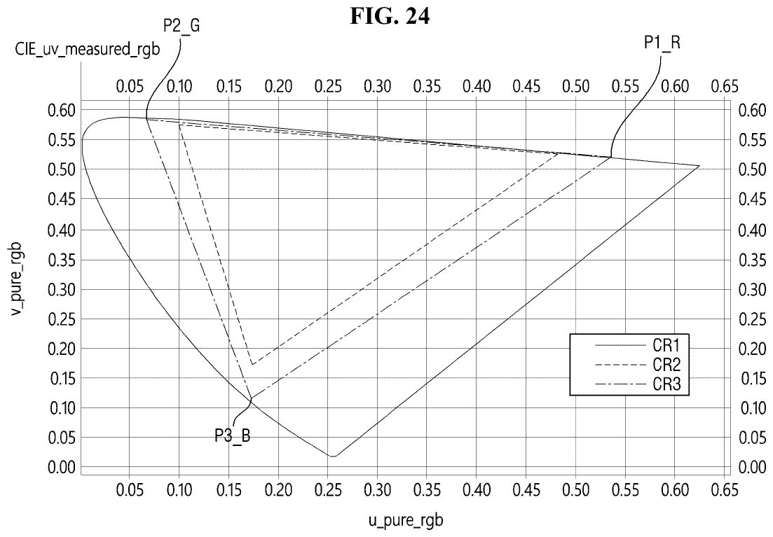

FIG. 24 is a chromaticity distribution diagram.

A first figure CR1 may be a figure representing a reference color space (e.g., a color space or color gamut of a visible light region), a second figure CR2 may be a figure representing a color space (or a color gamut) defined by Digital Cinema Initiatives (DCI)-P3, and a third figure CR3 may be a figure representing a color space (or a color gamut) defined based on measurements of an image of a display device according to an embodiment.

The third figure CR3 may include three vertices. A first vertex P1_R may represent a red region, a second vertex P2_G may represent a green region, and a third vertex P3_B may represent a blue region.

As illustrated in FIG. 24, the third figure CR3 including the first vertex P1_R may surround the second figure CR2 and have a larger area than the second figure CR2. Therefore, the display device according to an embodiment may satisfy the color purity defined in DCI-P3. For example, in the display device according to an embodiment, the color purity of red may be improved, and color mixing may be prevented. For example, the display device according to an embodiment may provide high color purity corresponding to about 99.2% of the color space defined by DCI-P3. For example, the display device according to an embodiment may show a low color mixing rate of about 0.3%.

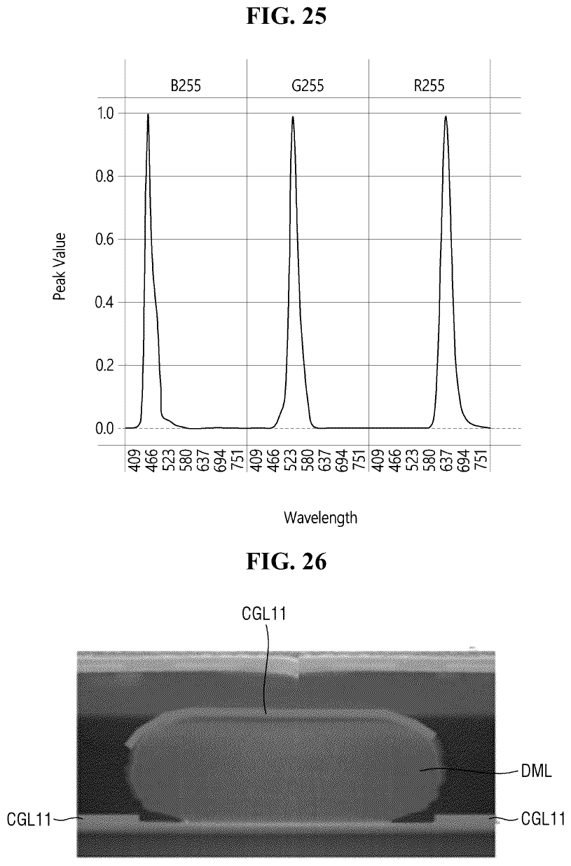

FIG. 25 illustrates a peak value for each wavelength of a display device 1 according to an embodiment.

As illustrated in FIG. 25, in the display device 1 according to an embodiment, the peak value for each wavelength may be maintained at a high value with almost no noise in a red wavelength region R255, a green wavelength region G255, and a blue wavelength region B255. Therefore, in the display device 1 according to an embodiment, color purity may be improved.

FIG. 26 is a focused ion beam (FIB) image of a dummy layer DML of a display device according to an embodiment.

As illustrated in FIG. 26, the dummy layer DML may have an oval cross section.

A layer disposed on the dummy layer DML may be an n-type charge generation layer CGL11. The n-type charge generation layer CGL11 may be broken around the dummy layer DML by the dummy layer DML.

According to an embodiment, since a light emitting layer OL and a wavelength conversion member WC are disposed adjacent to each other, there is a possibility of color mixing between adjacent pixels. However, since the dummy layer DML is disposed on a pixel defining layer between adjacent pixels, the color mixing phenomenon may be minimized.

According to an embodiment, in case that the dummy layer DML has a color different from the colors provided from adjacent pixels, it may block light provided from the light emitting layer OL of the adjacent pixels, thereby further improving the color mixing prevention effect. For example, in case that the light emitting layer OL of the pixels provides blue light, the dummy layer DML may have a color (e.g., red or green) different from blue. For example, it is difficult for blue light emitted from the light emitting layer OL of one pixel to enter a wavelength conversion layer corresponding to an adjacent pixel. This is because the dummy layer DML of a color different from blue is disposed on the pixel defining layer between the adjacent pixels. Therefore, the problem that a pixel emits light during a light emission period of another pixel adjacent to the pixel may be solved. Ultimately, color mixing between adjacent pixels may be prevented, and color purity may be improved.

In a display device according to an embodiment, color mixing may be prevented, and color purity may be improved. Therefore, the image quality of the display device may be improved.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a substrate;
a first electrode on the substrate;
a pixel defining layer on the first electrode;
a dummy layer on the pixel defining layer;
a light emitting layer on the first electrode and the dummy layer; and
a second electrode on the light emitting layer,
wherein at least one side surface of the dummy layer has a round cross section.

2. The display device of claim 1, wherein the dummy layer has an oval cross section.

3. The display device of claim 1, wherein the dummy layer comprises:
a lower dummy layer comprising reverse-tapered side surfaces; and
an upper dummy layer comprising forward-tapered side surfaces.

4. The display device of claim 3, wherein the lower dummy layer has a width that gradually increases as being farther from a lower surface of the lower dummy layer along a first direction from the dummy layer toward the first electrode on the dummy layer, and the upper dummy layer has a width that gradually decreases as being closer to an upper surface of the upper dummy layer along the first direction.

5. The display device of claim 1, wherein the dummy layer has at least one of green, red, blue, and black colors.

6. The display device of claim 1, further comprising:
a color filter and a light blocking pattern portion disposed on the light emitting layer on the first electrode,
wherein the dummy layer and at least one of the color filter and the light blocking pattern portion have a same color.

7. The display device of claim 1, wherein
the pixel defining layer defines a light emitting area corresponding to the light emitting layer on the first electrode, and
the dummy layer is disposed around the light emitting area in plan view.

8. The display device of claim 7, wherein
the pixel defining layer defines a plurality of light emitting areas, and
at least a portion of the dummy layer is disposed between adjacent light emitting areas in plan view.

9. The display device of claim 1, wherein the dummy layer has a line shape in plan view.

10. The display device of claim 1, wherein the dummy layer has a dotted shape in plan view.

11. The display device of claim 1, wherein the dummy layer comprises an organic material.

12. The display device of claim 11, wherein the dummy layer comprises a negative type organic material.

13. The display device of claim 1, wherein the dummy layer has a thickness of about 1 μm to about 6 μm.

14. The display device of claim 1, wherein the light emitting layer on the first electrode and the light emitting layer on the dummy layer are disconnected from each other.

15. The display device of claim 14, wherein the light emitting layer comprises:
a main light emitting layer on the first electrode; and
a dummy light emitting layer disposed on the dummy layer and separated from the main light emitting layer.

16. The display device of claim 1, wherein the second electrode disposed on the light emitting layer to overlap the first electrode and the second electrode disposed on the light emitting layer to overlap the dummy layer are disconnected from each other.

17. The display device of claim 16, wherein the second electrode comprises:
a main second electrode disposed on the light emitting layer to overlap the first electrode; and
a dummy second electrode disposed on the light emitting layer to overlap the dummy layer and separated from the main second electrode.

18. The display device of claim 1, further comprising:
a thin-film encapsulation layer on the second electrode,
wherein the thin-film encapsulation layer covers a broken portion of the light emitting layer.

19. The display device of claim 18, further comprising:
a capping layer between the second electrode and the thin-film encapsulation layer,
wherein the capping layer covers the broken portion of the light emitting layer.

20. The display device of claim 18, further comprising:
a wavelength conversion member on the thin-film encapsulation layer.

21. A method of fabricating a display device, the method comprising:
forming a first electrode on a substrate;
forming a pixel defining layer on the first electrode;
forming a dummy layer on the pixel defining layer;
forming a light emitting layer on the first electrode and the dummy layer; and
forming a second electrode on the light emitting layer,
wherein at least one side surface of the dummy layer has a round cross section.

22. The method of claim 21, wherein the forming of the dummy layer comprises:
forming an organic material layer by applying a negative type organic material to an entire surface of the substrate including the first electrode and the pixel defining layer;
placing a mask, which comprises an opening, above the organic material layer;
exposing the organic material layer through the mask such that the organic material layer includes an exposed portion and an unexposed portion; and
forming the dummy layer on the pixel defining layer by developing the exposed portion of the organic material layer to selectively leave the exposed portion among the exposed portion and the unexposed portion of the organic material layer.

23. The method of claim 21, wherein the dummy layer has an oval cross section.

24. The method of claim 23, wherein the dummy layer comprises:
a lower dummy layer comprising reverse-tapered side surfaces; and
an upper dummy layer comprising forward-tapered side surfaces.

25. The method of claim 24, wherein the lower dummy layer has a width that gradually increases as being farther from a lower surface of the lower dummy layer along a first direction from the dummy layer toward the first electrode, and the upper dummy layer has a width that gradually decreases as being closer to an upper surface of the upper dummy layer along the first direction.

26. The method of claim 21, wherein the dummy layer has at least one of green, red, blue, and black colors.

27. The method of claim 21, further comprising:
forming a color filter and a light blocking pattern portion on the light emitting layer on the first electrode,
wherein the dummy layer and at least one of the color filter and the light blocking pattern portion have a same color.

28. The display device of claim 21, wherein
the pixel defining layer defines a light emitting area corresponding to the light emitting layer on the first electrode, and
the dummy layer is disposed around the light emitting area in plan view.
